(19) United States
(12) Patent Application Publication
(10) Pub. No.: US 2006/0076046 A1
(43) Pub. Date: Apr. 13, 2006

(54) Thermoelectric device structure and apparatus incorporating same

(75) Inventors: Uttam Ghoshal, Austin, TX (US); Tat Ngai, Austin, TX (US); Srikanth B. Samavedam, Austin, TX (US); Zhengmao Ye, Austin, TX (US); Andrew C. Miner, Austin, TX (US)

Correspondence Address: ZAGORIN O'BRIEN GRAHAM LLP, 7600B N. CAPITAL OF TEXAS HWY., SUITE 350, AUSTIN, TX, 78731, US

(73) Assignee: NanoCoolers, Inc.

(21) Appl. No.: 11/124,365

(22) Filed: May 6, 2005

Related U.S. Application Data
(60) Provisional application No. 60/617,513, filed on Oct. 8, 2004.
(60) Provisional application No. 60/649,273, filed on Feb. 2, 2005.
(60) Provisional application No. 60/659,541, filed on Mar. 8, 2005.

(51) Int. Cl. H01L 35/30; H01L 35/28

(52) U.S. Cl. 136/205; 136/212

(57) ABSTRACT

In certain embodiments, a thermoelectric device apparatus includes a plurality of laterally spaced-apart electrodes disposed upon a supporting structure, and at least one complementary pair of thermoelectric elements, each thermoelectric element coupling an electrode to a laterally adjacent electrode. Such a structure reduces the need for solder joints or other structures or mechanisms to attach multiple substrates, components, or assemblies together to form a thermoelectric device.

### CROSS-REFERENCE TO RELATED APPLICATION(S)

This application claims the benefit under 35 U.S.C. § 119(e) of U.S. Provisional Application No. 60/617,513, filed Oct. 8, 2004, entitled “MONOLITHIC THIN-FILM THERMOELECTRIC DEVICE INCLUDING COMPLEMENTARY THERMOELECTRIC MATERIALS” by Srikanth B. Samavedam, et al., which application is hereby incorporated by reference.

This application claims the benefit under 35 U.S.C. § 119(e) of U.S. Provisional Application No. 60/649,273, filed Feb. 2, 2005, entitled “LATERAL THERMOELECTRIC DEVICE STRUCTURE AND RELATED APPARATUS” by Uttam Ghoshal, et al., which application is hereby incorporated by reference.

This application claims the benefit under 35 U.S.C. § 119(e) of U.S. Provisional Application No. 60/659,541, filed Mar. 8, 2005, entitled “LATERAL THERMOELECTRIC DEVICE STRUCTURE AND RELATED APPARATUS” by Uttam Ghoshal, et al., which application is hereby incorporated by reference.

### BACKGROUND

1. Field of the Invention

The present invention generally relates to thermoelectric device structures.

2. Description of the Related Art

Thermoelectric devices and materials are well-known in the art and a wide variety of configurations, systems and exploitations thereof will be appreciated by those skilled in the art. In general, exploitations include those in which a thermal potential is developed as a consequence of an electromotive force (typically voltage) across an appropriate material, material interface or quantum structure, as well as those in which an electromotive force (typically voltage) results from a thermal potential across an appropriate material, material interface or quantum structure. Peltier, or thermoelectric, coolers and refrigerators operate on the former principal, while thermoelectric power generators employ the second.

Electronic devices such as microprocessors, laser diodes, etc. generate significant amounts of heat during operation. If the heat is not dissipated, it may adversely affect the performance of these devices. Typical cooling systems for small devices are based on passive cooling methods and active cooling methods. The passive cooling methods include heat sinks and heat pipes. Such passive cooling methods may provide limited cooling capacity due to spatial limitations. Active cooling methods may include use of devices such as mechanical vapor compression refrigerators and thermoelectric coolers. Vapor compression based cooling systems generally require significant hardware such as a compressor, a condenser and an evaporator. Because of the large required volume, moving mechanical parts, poor reliability and associated cost of the hardware, use of such vapor compression based systems might not be suitable for cooling small electronic devices.

Thermoelectric cooling, for example using a Peltier device, provides a suitable cooling approach for cooling small electronic devices. A typical Peltier thermoelectric cooling device includes a semiconductor with two metal electrodes. When a voltage is applied across these electrodes, heat is absorbed at one electrode producing a cooling effect, while heat is generated at the other electrode producing a heating effect. The cooling effect of these thermoelectric Peltier devices can be utilized for providing solid-state cooling of small electronic devices.

Unlike conventional vapor compression-based cooling systems, thermoelectric devices have no moving parts. The lack of moving parts increases reliability and reduces maintenance of thermoelectric cooling devices as compared to conventional cooling systems. Thermoelectric devices may be manufactured in small sizes making them attractive for small-scale applications. In addition, the absence of refrigerants in thermoelectric devices has environmental and safety benefits. Thermoelectric coolers may be operated in a vacuum and/or weightless environments and may be oriented in different directions without affecting performance.

### SUMMARY

A complementary, lateral, thermoelectric device structure is provided. Such a device may include thermoelectric elements of opposing conductivity types coupled electrically in series and thermally in parallel by associated electrodes on a single supporting structure, reducing the need for solder joints or other structures or mechanisms to attach multiple components or assemblies together.

One aspect of the invention provides a thermoelectric device apparatus including a plurality of laterally spaced-apart electrodes disposed upon a supporting structure, and at least one complementary pair of thermoelectric elements, each thermoelectric element coupling an electrode to a laterally adjacent electrode.

In some embodiments, the electrodes are non-uniform in width between adjacent thermoelectric elements coupled thereto. In some embodiments, the supporting structure comprises a layer that is formed in a monolithic process for also forming the electrodes and complementary thermoelectric elements. In some embodiments, the supporting structure includes a layer formed after formation of the electrodes and complementary thermoelectric elements. In some embodiments, the supporting structure further comprises a carrier substrate attached after monolithic formation of the electrodes, the complementary thermoelectric elements, and the supporting structure layer.

In some embodiments, the supporting structure includes a layer formed before formation of the electrodes and complementary thermoelectric elements. The supporting structure may include a monolithic fabrication substrate upon which the supporting structure layer is disposed.

In some embodiments, the supporting structure layer includes a material chosen from the group consisting of dielectrics having a thermal conductivity of less than 0.1 W/m-K, polymers based upon paraxylylene and its substituted derivatives, fluoropolymers, and aerogels.

In some embodiments, the plurality of laterally spaced-apart electrodes includes a first group of at least one electrode and a second group of at least two electrodes. The electrodes of said first and second groups of electrodes are generally coplanar and are disposed within a first region in an alternating, laterally spaced apart manner. The at least one complementary pair of thermoelectric elements includes alternating complementary thermoelectric elements, each element coupling together an electrode of the first group and an adjacent electrode of the second group within the first region.

In some embodiments, electrodes of at least one of the first and second groups of electrodes are tapered in width within the first region. In some embodiments each respective lateral space between adjacent electrodes of a respective pair of adjacent electrodes is less than an electron-phonon thermalization length of a thermoelectric material comprising the respective thermoelectric element coupling together said respective pair of adjacent electrodes. Such lateral space may be less than 1 μm.

In some embodiments, the supporting structure of the apparatus includes a supporting layer group disposed on a supporting base, the supporting layer group having a substantially lower thermal conductivity than the supporting base. The supporting layer group may include a material such as a dielectric having a thermal conductivity of less than 0.1 W/m-K, a polymer based upon paraxylylene and its substituted derivatives, a fluoropolymer such as, for example, polytetrafluoroethylene (PTFE), and/or an aerogel. The supporting base may include a material such as a semiconductor and/or a metal.

In some embodiments the thermoelectric device apparatus includes thermal conduction means for providing thermal conduction between the electrodes of the second group and the supporting base that is substantially greater than any thermal conduction between the electrodes of the first group and the supporting base. The first and second groups of electrodes may be interdigitated electrodes, such that the first group of electrodes extend beyond one side of the first region farther than the second group of electrodes, and the second group of electrodes extend beyond a side opposite the one side of the first region farther than the first group of electrodes. In some embodiments, the thermal conduction means is thermally coupled to electrodes of the second group outside the first region. In some embodiments, the apparatus also includes a first pad disposed outside the first region which is thermally coupled to one or more electrodes of the first group and electrically isolated from all but at most one electrode of the first group.

In another aspect, the invention provides a thermoelectric device apparatus including a plurality of laterally spaced-apart electrodes, each of said electrodes being thicker in a region between opposing longitudinal edges thereof than along said opposing longitudinal edges, and a plurality of thermoelectric elements, each coupling together at least respective longitudinal edges of laterally adjacent electrodes.

In still another aspect, the invention provides a complementary lateral thermoelectric device that is disposed upon a supporting layer comprising a material chosen from the group consisting of polymers based upon paraxylylene and its substituted derivatives, fluoropolymers, and aerogels.

In some embodiments of the present invention, a lateral thermoelectric device operates to generate power from an externally imposed temperature gradient. In other embodiments of the present invention, a lateral thermoelectric device operates as a cooler to generate a temperature difference between hot and cold electrodes when the electrodes are coupled to an externally imposed electrical potential.

The foregoing is a summary and thus contains, by necessity, simplifications, generalizations and omissions of detail. Consequently, those skilled in the art will appreciate that the foregoing summary is illustrative only and that it is not intended to be in any way limiting of the invention. The inventive concepts described herein are contemplated to be used alone or in various combinations. Other aspects, inventive features, and advantages of the present invention, as defined solely by the claims, may be apparent from the detailed description set forth below.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a cross-sectional view of a lateral thermoelectric device in accordance with some embodiments of the present invention.

FIG. 2A illustrates a cross-sectional view of a thermoelectric device in accordance with some embodiments of the present invention.

FIG. 2B illustrates the variation of electron and phonon temperatures within an exemplary thermoelectric device.

FIGS. 3-9 illustrate cross-sectional views of a lateral thermoelectric device structure in progressive stages of manufacture consistent with some embodiments of the present invention, in particular:

FIGS. 3A-3C illustrate a method for forming thermoelectric materials of complementary conductivity type on a single substrate consistent with some embodiments of the present invention.

FIGS. 4A-4C illustrate a method for forming thermoelectric materials of complementary conductivity type on a single substrate consistent with some embodiments of the present invention.

FIGS. 5A-5C illustrate a method for forming a thermoelectric device from thermoelectric materials of complementary conductivity type on a single substrate consistent with some embodiments of the present invention.

FIGS. 6A-6C illustrate a method for forming electrical electrodes separated by gaps on a substrate consistent with some embodiments of the present invention.

FIGS. 7A-7F illustrate a method for forming a thermoelectric device from thermoelectric materials of complementary conductivity type on a single substrate consistent with some embodiments of the present invention.

FIGS. 8A-8E illustrate a method for forming a thermoelectric device from thermoelectric materials of complementary conductivity type on a single substrate consistent with some embodiments of the present invention.

FIGS. 9A-9F illustrate a method for forming electrical electrodes separated by gaps on a substrate consistent with some embodiments of the present invention.

FIG. 10A illustrates a plan view of a thermoelectric device structure consistent with some embodiments of the present invention.

FIG. 10B illustrates a plan view of a thermoelectric device structure consistent with some embodiments of the present invention.

FIG. 11 illustrates a plan view of a thermoelectric device structure consistent with some embodiments of the present invention.

FIG. 12 illustrates a plan view of a thermoelectric device structure consistent with some embodiments of the present invention.

FIG. 13 illustrates a plan view of a thermoelectric device structure consistent with some embodiments of the present invention.

FIG. 14 illustrates a plan view of a thermoelectric device structure consistent with some embodiments of the present invention.

FIG. 15 illustrates a plan view of a thermoelectric device structure consistent with some embodiments of the present invention.

FIG. 16 illustrates a plan view of a thermoelectric device structure consistent with some embodiments of the present invention.

FIG. 17 illustrates a plan view of a thermoelectric device structure consistent with some embodiments of the present invention.

FIGS. 18A-18I illustrate a method for forming a thermoelectric device structure from thermoelectric materials of complementary conductivity type formed on a single substrate consistent with some embodiments of the present invention.

FIGS. 19A-19G illustrate a method for forming a thermoelectric device structure from thermoelectric materials of complementary conductivity type formed on a single substrate consistent with some embodiments of the present invention.

FIGS. 20A-20G illustrate a method for forming a thermoelectric device structure from thermoelectric materials of complementary conductivity type on a single substrate consistent with some embodiments of the present invention.

FIG. 21A illustrates a cross-sectional view of a vertical heat rejection structure consistent with some embodiments of the present invention.

FIG. 21B illustrates a cross-sectional view of a vertical heat rejection structure consistent with some embodiments of the present invention.

FIGS. 22A-22D illustrate a cross-sectional view of a vertical heat rejection structure consistent with some embodiments of the present invention in several stages of fabrication.

FIG. 23 illustrates a three-dimensional view of a vertical heat rejection structure consistent with some embodiments of the present invention.

FIG. 24A illustrates a plan view of a thermoelectric device structure consistent with some embodiments of the present invention.

FIG. 24B illustrates a plan view of a thermoelectric device structure consistent with some embodiments of the present invention.

FIGS. 25A-25F illustrate a method for forming a thermoelectric device from thermoelectric materials of complementary conductivity type on a single substrate consistent with some embodiments of the present invention.

FIG. 26 illustrates a cross-sectional view of a thermoelectric device structure consistent with some embodiments of the present invention.

FIG. 27 shows a top view of an exemplary thermoelectric device structure.

FIG. 28 shows another view of the exemplary thermoelectric device structure of FIG. 27.

FIG. 29 shows a cross-sectional view of an exemplary thermal pad structure.

FIG. 30 shows a cross-sectional view of an exemplary thermal pad structure.

FIGS. 31A-31F depict cross-sectional views of various exemplary conductive rib structures.

FIGS. 32A and 32B show a cross-sectional view of a conductive rib structure at incomplete stages of its fabrication.

FIGS. 33A and 33B show a cross-sectional view of a thermoelectric device employing a conductive rib structure at incomplete stages of its fabrication.

FIG. 34 shows a cross-sectional view of a lateral thermoelectric device formed on a structured substrate.

FIGS. 35A-35E depict cross-sectional views of a lateral thermoelectric device formed on a structured substrate at various incomplete stages of fabrication.

FIG. 36 shows a top view of a lateral thermoelectric device formed on a structured substrate corresponding to the side-view of FIG. 34.

The use of the same reference symbols in different drawings indicates similar or identical items.

### DETAILED DESCRIPTION

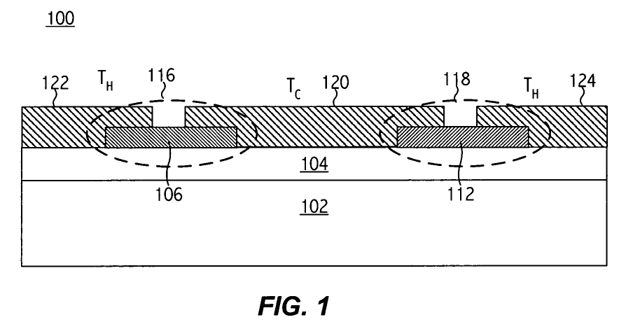

Referring now to FIG. 1, an exemplary lateral complementary thermoelectric device 100 includes three electrodes 122, 120, and 124 formed on the same side of a substrate 102. A low thermal conductivity layer 104 is formed on the substrate 102 to reduce heat conduction via the substrate 102 of the device. The layer 104 may also function as an etch stop layer. The substrate 102 and any optional overlayers (e.g., layer 104) act as a supporting structure for the thermoelectric device.

A thermoelectric element 106 of a first type (e.g., n-TE material) and a thermoelectric element 112 of a second type (e.g., p-TE material) are formed on the low conductivity layer 104 (i.e., the upper surface of the supporting structure). The electrode 122 overlaps and makes electrical and thermal contact to the thermoelectric element 106, the electrode 120 overlaps and makes electrical and thermal contact to both thermoelectric element 106 and thermoelectric element 112, and electrode 124 overlaps and makes electrical and thermal contact to thermoelectric element 112. In operation, an electrical current is caused to flow through the thermoelectric element 106 and thermoelectric element 112, and as a result at least one of the electrodes has a temperature (e.g., T_{H}) substantially different from the temperature (e.g., T_{C}) of another electrode. As shown in FIG. 1, both electrodes 122 and 124 operably reach a temperature of T_{H}, while electrode 120 operably reaches a temperature of T_{C}.

Typical thermoelectric devices are limited by low efficiency as compared to conventional cooling systems. In general, the efficiency of a thermoelectric device depends on material properties and is quantified by a figure of merit (ZT):
ZT=S²Tσ/λ,
where S is the Seebeck coefficient, which is a property of a material, T is the average temperature of the thermoelectric material, σ is the electrical conductivity of the thermoelectric material, and λ is the thermal conductivity of the thermoelectric material. Typical thermoelectric devices have a thermoelectric figure of merit less than 1. In comparison, a thermoelectric device that is as efficient as a conventional vapor compression refrigerator would have a figure of merit of approximately 3.

Given this relationship for the figure of merit, a thermoelectric device utilizing a material having high electrical conductivity and low thermal conductivity generally has a high figure of merit. This requires reduction in thermal conductivity without a significant reduction in electrical conductivity. Various approaches have been proposed to increase the figure of merit of thermoelectric devices by decreasing the thermal conductivity of the material while retaining high electrical conductivity.

But the efficiency of a thermoelectric device is not determined solely by the properties of the thermoelectric material. Heat flow in a thermoelectric device structure is parasitic to the extent that it acts to reduce the efficiency or effectiveness of the device. For example, in a thermoelectric cooling device the cold side of the device is thermally coupled to the load, or object to be cooled. Conduction of heat through a substrate toward the cold side from some external source increases the total amount of heat to be removed from the system at the cold side, and so decreases the effectiveness of the cooler by decreasing the amount of heat that can be removed from the load for the same power consumption. And, of course, the thermal conduction within a thermoelectric cooling device that carries heat from the hot side to the cold side during operation reduces the efficiency of the cooler.

Similar effects occur when thermoelectric devices are operated to generate power from an imposed temperature differential. In this case, thermal conduction from the hot side to the cold side of the device reduces the temperature gradient, reducing the amount of power that the device can generate. Thus, reducing parasitic heat flow increases the efficiency and effectiveness of thermoelectric devices regardless of the mode in which they operate.

A thermoelectric device with a figure-of-merit of greater than 1 may be achieved in part by reducing the thermal conductivity of the thermoelectric device without significant reduction in electrical conductivity.

Materials referred to as “thermoelectric materials” have large values of the Seebeck coefficient (S, above) compared to other materials. They are often heavily doped semiconductors or semimetals, and their alloys and superlattices. Thermoelectric materials can be shaped to form thermoelectric elements, or thermoelectric elements. When a pair of electrodes is connected to opposites sides of a thermoelectric element the structure is referred to as a thermoelectric device. Some thermoelectric device configurations include an n-type thermoelectric device (e.g., thermoelectric device 116 of FIG. 1) and a p-type thermoelectric device (e.g., thermoelectric device 118 of FIG. 1) coupled electrically in series and thermally in parallel. For example, in operation, a voltage is applied to electrodes 122 and 124 of thermoelectric device structure 100 creating a Peltier effect transferring thermal energy away from electrode 120 towards electrodes 122 and 124. A figure of merit greater than one may be achieved by reducing the thermal conductivity component (λ) of the figure of merit (i.e., ZT=S²Tσ/λ).

The thermal conductivity of the thermoelectric device (λ) includes two components, i.e., the thermal conductivity due to electrons (referred to as electron thermal conductivity, λₑ, hereinafter) and the thermal conductivity due to phonons (referred to as phonon thermal conductivity, λₚ, hereinafter). A phonon is a vibrational wave in a solid that may be viewed as a particle having energy and a wave length. Phonons carry heat and sound through the solid, moving at the speed of sound in the solid. Thus, λ=λₑ+λₚ. Typically, λₚ forms the dominant component of λ. The value of λ may be reduced by reducing the value of either λₑ or λₚ. A reduction in λₑ reduces electrical conductivity σ, thereby producing an overall reduction in the value of figure of merit, ZT. However, a reduction in λₚ without significantly affecting λₑ may reduce the value of λ without affecting σ and may produce a corresponding increase of the figure of merit.

The reduction of phonon thermal conductivity λₚ may be accomplished by decoupling and separating the phonon conduction from the electron conduction by the use of thermoelectric devices that are “short” in the direction of current flow and by selectively attenuating phonon conduction using a phonon conduction impeding structure, without significantly affecting the electron conduction. The use of a phonon conduction impeding material and short thermoelectric elements in thermoelectric device structure 100 reduce the value of λₚ, thereby reducing the value of λ and increasing the figure of merit.

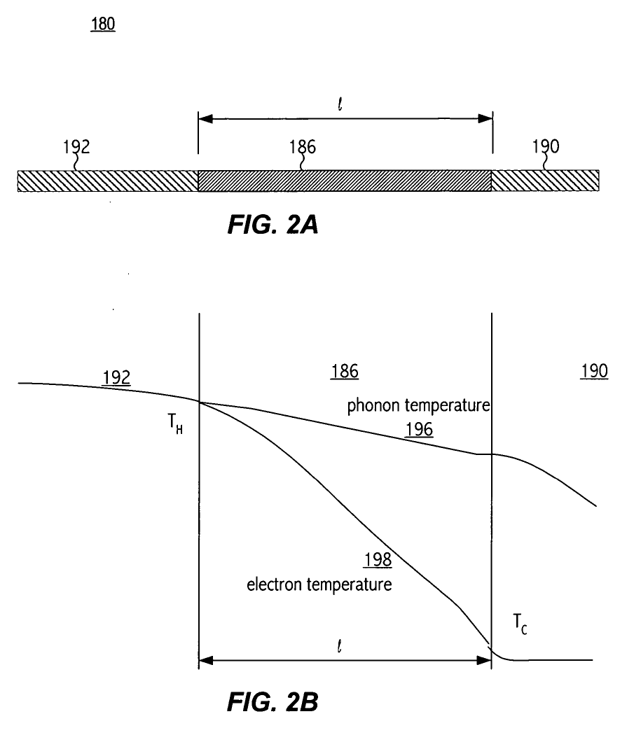

For example, thermoelectric device 180 of FIG. 2A includes thermoelectric element 186 having a transport length l in the direction of current flow. An electrical potential is applied across thermoelectric element 186 such that the electric current flows from electrode 192 to electrode 190 and electrons flow in the opposite direction. Once injected into thermoelectric element 186 from electrode 190, the electrons are not in thermal equilibrium with the phonons in thermoelectric element 186 for a finite distance Λ from the surface of electrode 190 and thermoelectric element 186. This finite distance Λ is known as electron-phonon thermalization length. The electron-phonon thermalization length is the distance traveled by electrons after which thermal equilibrium between electrons and phonons occurs. For example, when a material is heated, the electrons start moving to conduct the thermal energy, collide with phonons, and share their energy with the phonons. As a result, the temperature of phonons increases until a thermal equilibrium between the electrons and the phonons is achieved. In some embodiments of the invention, the transport length l of thermoelectric elements is less than the distance Λ. Hence, the electrons and phonons are not in thermal equilibrium in thermoelectric element 186 and do not affect each other in the energy transport.

Once the phonon transport process and the electron transport process are separated, the difference in the thermal conduction mechanisms in materials having a low acoustic velocity (i.e., phonon conduction impeding materials) and other materials may be exploited. Thermal conduction in metals (liquid as well as solid) is due to the transport of electrons and phonons. Electrode 190 may include a phonon conduction impeding medium (i.e., a material having a low acoustic velocity) having a high electron conductivity. Phonon conduction impeding materials include (without limitation) liquid metals, interfaces created by cesium doping, and solid metals such as indium, lead and thallium that have very low acoustic velocities, i.e., acoustic velocities less than 1200 m/s. The net effect is that phonon thermal conductivity between the electrodes of the thermoelectric cooler is significantly reduced, i.e., λₚ<0.5 W/m-K, without reducing electrical conductivity.

As used herein, “liquid metal” refers to metals that are in a liquid state during at least a portion of operating temperature of interest. Examples of liquid metals include at least gallium and gallium alloys. Liquid metals or liquid metal alloys generally have less ionic order and a less regular crystal structure than solid metals. This results in lower acoustic velocities and negligible phonon thermal conductivity λₚ in the liquid metals as compared to phonon thermal conductivity of solid metals. The phonon thermal conductivity of the liquid metals is less than the phonon conductivity of typical solid-phase glasses or polymers with thermal conductivity values less than 0.1 W/m-K. As a result, the thermal conductivity in liquid metals is predominantly due to electrons. However, the electronic conduction is not similarly impeded because the phonon conduction impeding medium has a high electronic conductivity and the electrons can tunnel through the interface barriers with minimal resistance. In other words, the electronic conduction is effectively decoupled or separated from the phonon-conduction. A similar process occurs in other conducting materials that have a low acoustic velocity, such as metals (In, Tl, Pt-coated In), and conducting polymers (doped polyacetylene, doped polypyrrole, doped pentacene, etc.). Such phonon conduction impeding materials are described in additional detail in co-pending U.S. patent application Ser. No. 11/020,531, filed on Dec. 23, 2004, entitled “Monolithic Thin-Film Thermoelectric Device Including Complementary Thermoelectric Materials,” by Ghoshal, et al., which application is hereby incorporated by reference in its entirety.

Notwithstanding the type of material used for electrode 190, mismatches of acoustic velocities in the thermoelectric material 186 and electrode 190 introduce interface thermal resistances such as Kapitza thermal boundary resistances. The associated reduction of phonon thermal conductivity λₚ (in some cases to negligible amounts) reduces the thermal conductivity in thermoelectric device 180. In some devices, the thermal conductivity may be predominantly due to electron thermal conductivity λₑ, i.e., λ→λₑ. The reduction in thermal conductivity contributes to an improved figure of merit.

FIG. 2B illustrates the variation of electron and phonon temperatures within exemplary thermoelectric device 180. The temperature of electrode 190 is T_{C} and the temperature of electrode 192 is T_{H}. The temperature of electrons in electrode 190 is approximately T_{C}, while the temperature of electrons in electrode 192 is approximately T_{H}. The variation of temperature of electrons in thermoelectric element 186 (i.e., temperature 196) is nonlinear and is governed by heat conduction equations. The temperature of phonons in electrode 192 is approximately equal to T_{H} because of the electron-phonon coupling within the solid. However, in electrode 190 (i.e., the electrode including a phonon conduction impeding material), the temperature of phonons in the thermoelectric layer at the thermoelectric element interface is not equal to the electrode temperature because of the thermal impedance of the phonons at the interface. The temperature of the phonons in thermoelectric element 186 (i.e., temperature 198) varies between the temperature of electrode 192, i.e., T_{H}, and the temperature of phonons in electrode 190, as shown in FIG. 2B. The electron and the phonon temperatures in thermoelectric element 186 are not in equilibrium.

A similar analysis can be undertaken for the situation of a p-type thermoelectric element, in which the current carriers are holes, rather than electrons, and thus flow in the direction of the electric current through the element.

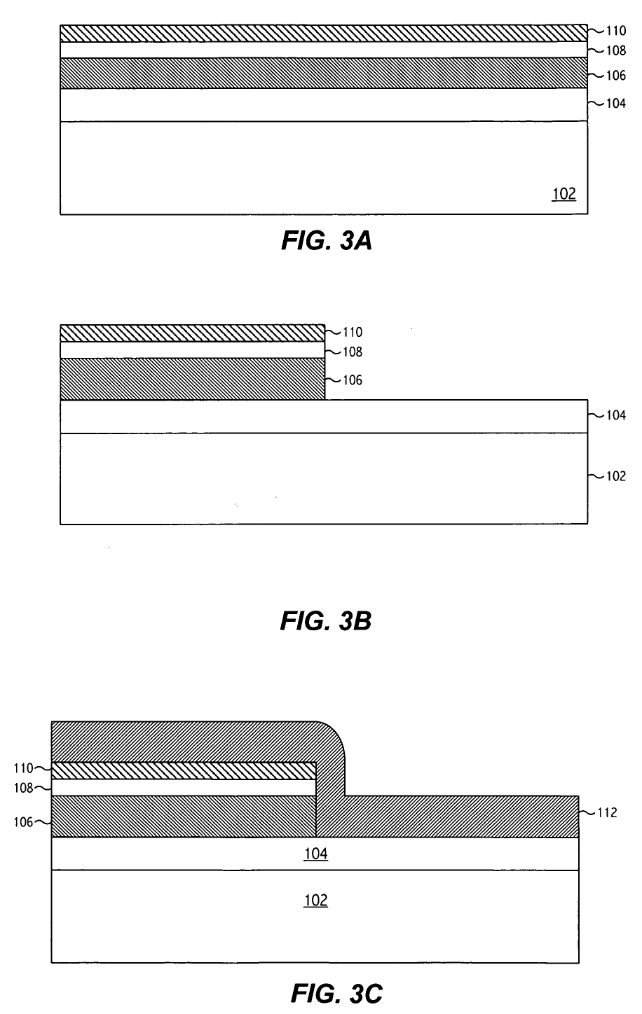

Referring now to FIG. 3A, one of several useful methods for fabricating a thermoelectric device in accordance with some embodiments of the present invention is next described. A substrate 102 may be silicon, glass (which has a lower thermal conductivity than silicon), gallium arsenide, indium phosphide, barium fluoride, sapphire, silicon-coated sapphire, polished ceramic, sintered alumina, borosilicate, metal, or other suitable material. A low thermal conductivity layer 104 is next formed on substrate 102 to reduce heat conduction via the substrate 102 of the device. In other embodiments, discussed in more detail below, the substrate 102 and any overlayers (e.g., layer 104) are removed before final deployment of the thermoelectric device. In some embodiments layer 104 may be absent or may merely function as an etch stop layer. As used herein, the substrate 102 may be viewed as a monolithic fabrication substrate, and also may be referred to as an original fabrication substrate.

A layer of thermoelectric material 106 is formed on low conductivity layer 104, i.e. the upper surface of the supporting structure. Thermoelectric material 106 may be formed using physical vapor deposition (PVD), electro-deposition, metallo-organic chemical vapor deposition (MOCVD), molecular beam epitaxy (MBE), or other suitable technique. In some embodiments of the present invention, thermoelectric material 106 has a high power factor (S²σ), as discussed above. Exemplary thermoelectric semiconductor materials include p-type Bi_{0.5}Sb_{1.5}Te₃, n-type Bi₂Te_{2.8}Se_{0.2}, n-type Bi₂Te₃, superlattices of constituent compounds such as Bi₂Te₃/Sb₂Te₃ superlattices, lead chalcogenides such as PbTe or skutterudites such as CoSb₃, traditional alloy semiconductors SiGe, BiSb alloys, or other suitable thermoelectric materials and nanowires of thermoelectric materials. The choice of material may depend upon the temperatures at which the thermoelectric device operates, as Z is often a strong function of temperature. Similarly, the thickness of the thermoelectric element may be determined by design or processing considerations, and is not particularly critical to the operation of the device. In certain embodiments, the layer of thermoelectric material 106 may be 1-2 μm thick.

In semiconductor processing in general, layers of materials can be used to stop an etching process automatically, alleviating the need to time such an etching process precisely. These etch stop layers are materials that are not effectively removed by the etchant in use. For example, etches for silicon often do not attack silicon nitride or silicon dioxide, and oxide etches are often benign to semiconductors and metal. Without etch stop layers structures are vulnerable to uncontrolled etching at imperfections, such as pinholes in thin layers, or grain boundaries in polycrystalline materials. The processes described below employ etch stop layers, but it is to be understood that those skilled in the art could form the device structures of the invention without them, and such minor modifications of exemplary processes described below do not depart from the spirit of the invention or its scope as determined solely by the claims.

In an exemplary embodiment, etch-stop layer 108 and etch-stop layer 110 are formed on the layer of thermoelectric material 106 before patterning the thermoelectric material 106. Etch-stop layer 110 may be platinum or other suitable etch-stop material. Etch-stop layer 108 may be oxide deposited by plasma-enhanced chemical vapor deposition (PECVD), which prevents diffusion of platinum into the thermoelectric material, or may be another suitable material. As illustrated in FIG. 3B, thermoelectric material 106 is patterned by typical semiconductor patterning techniques (e.g., forming a layer of photoresist on the substrate, selectively exposing the photoresist to define areas to be etched, and selectively etching those defined areas).

Referring to FIG. 3C, a layer of thermoelectric material 112 of a second type is next formed on the surfaces of the resulting structure. Thermoelectric material 112 may be any of the materials formed using any suitable techniques described herein, including those with reference to thermoelectric material 106. However, thermoelectric material 112 is a different type from thermoelectric material 106 (i.e., thermoelectric material 106 is p-type, and thermoelectric material 112 is n-type, or thermoelectric material 106 is n-type and thermoelectric material 112 is p-type). The thermoelectric material 112 may be etched to remove at least the portion overlying the etch stop layer 110, then the thermoelectric material 106 and thermoelectric material 112 may be etched to define the thermoelectric element 106 and thermoelectric element 112, and electrodes then formed coupled to such elements, to result in a structure such as that shown in FIG. 1. Details of such exemplary processing are described below.

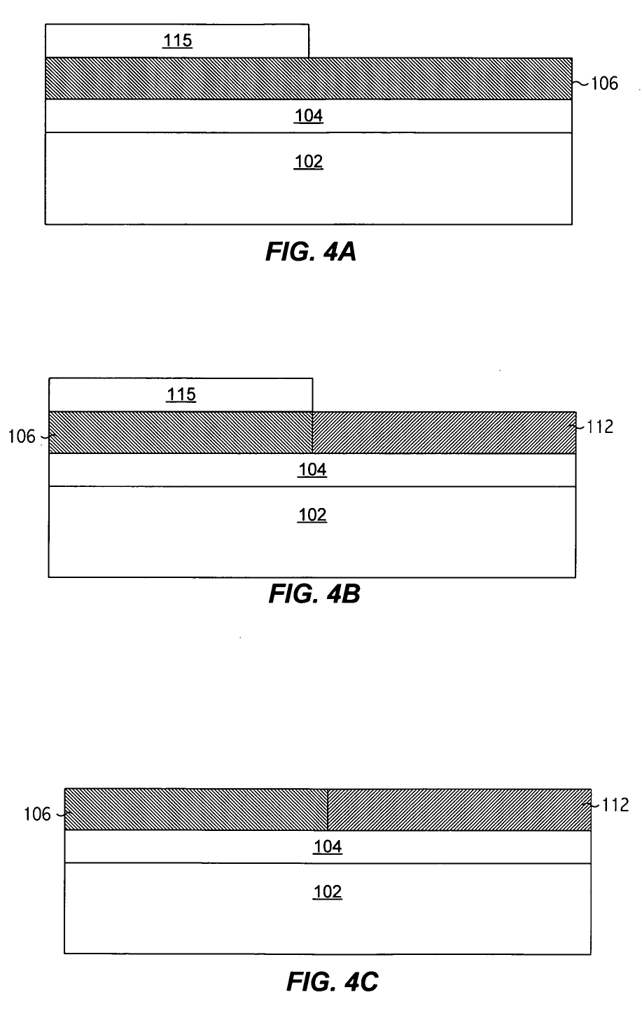

In some embodiments of the present invention, thermoelectric devices may be formed by a technique partially illustrated in FIGS. 4A-4C. Referring now to FIG. 4A, a p-type thermoelectric material 106 is formed on a layer 104 formed on the substrate 102 (as before). Thermoelectric material 106 may be formed from any of the thermoelectric materials and corresponding techniques for forming thermoelectric materials described elsewhere herein. A hard mask 115 is formed on thermoelectric material 106. Mask 115 may be PECVD oxide, spin-on-glass, or other suitable material formed by a suitable technique. Mask 115 is patterned to expose a portion of thermoelectric material 106. The exposed portion of thermoelectric material 106 is converted from p-type to n-type (or from n-type to p-type, as the case may be), resulting in converted thermoelectric material 112 shown in FIG. 4B. The conversion technique may include annealing thermoelectric material 106, implanting a material with high concentrations of majority carriers of a second type, diffusion from a thin-film formed on thermoelectric material 106, reaction with a thin-film formed on thermoelectric material 106, or other suitable technique. Mask 115 is then removed by wet etch, plasma etch, or other suitable technique, to expose thermoelectric material 106 and converted thermoelectric material 112, as illustrated in FIG. 4C.

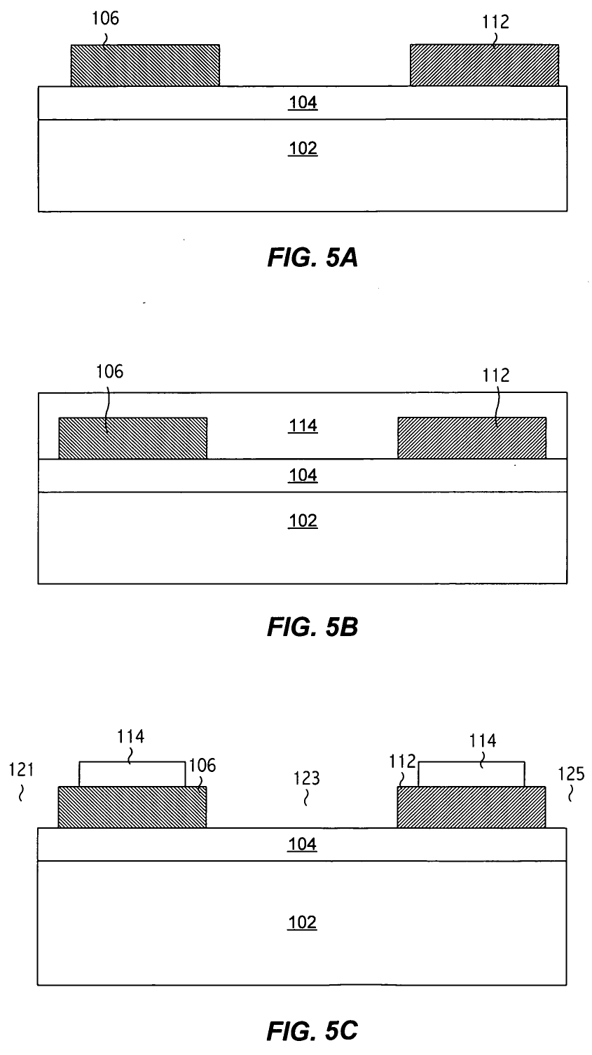

If thermoelectric material 112 is deposited after thermoelectric material 106 is patterned, as in FIG. 3C, thermoelectric material 112 may be patterned according to typical semiconductor patterning techniques. When thermoelectric material 112 is formed by conversion of thermoelectric material 106, both thermoelectric materials may be patterned during the same step. If so, thermoelectric material 106 and thermoelectric material 112 may be then patterned using a photolithography step and an etch step. In either case, the structure of FIG. 5A may result. Note that the order of forming the n-type thermoelectric element and the p-type thermoelectric element may be reversed. The extent of the thermoelectric element in the plane of the substrate perpendicular to current flow (i.e., the length of the thermoelectric element in a direction normal to the plane of the page, which frequently viewed as corresponding to the electrical width of the thermoelectric device) may be determined by design considerations and is not critical to the operation of the device. Likewise, the thickness of the thermoelectric element may be determined by design or processing considerations, and is not critical to the operation of the device. Exemplary thermoelectric elements may be approximately 1-8 μm thick. However, in some embodiments thermoelectric elements may be less than about 1 μm thick or greater than about 8 μm thick.

In some embodiments of the invention it may be desirable to use patterning techniques other than optical lithography, such as electron beam (e-beam) lithography, focused ion beam (FIB) lithography, and direct writing.

In some embodiments of the invention, after a typical etching step included in the patterning, etch-stop layer 108 may remain on thermoelectric material 106. Etch-stop layer 108 may then be removed by typical semiconductor processing techniques and dielectric layer 114 then formed on substrate 102, or dielectric layer 114 may incorporate etch-stop layer 108 into dielectric layer 114, to form the structure illustrated in FIG. 5B.

Referring to FIG. 5C, dielectric layer 114 is patterned by typical semiconductor processing techniques to form contact holes 121, 123, and 125 in dielectric layer 114. A layer of a conducting material, e.g., platinum, aluminum, or other suitable conductor, is formed by PVD, CVD, e-beam evaporation, or other suitable technique. The conductive layer is patterned and this step is followed by removal of dielectric layer 114 to form electrodes (i.e., “contacts”) 122, 120, and 124, which are electrically and thermally coupled to thermoelectric devices 116 and 118, as illustrated in FIG. 1. In one embodiment of the invention, electrode 120 is approximately 20 μm wide (i.e., in a direction in the plane of the page and parallel to the current flow). In other embodiments of the invention the width of electrode 120 may be 10 μm or 5 μm or some other dimension chosen to optimize the performance of a particular device. In some cases, such as that depicted in FIG. 12, the width of the electrodes varies.

FIG. 1 depicts an exemplary embodiment in which thermoelectric device 116 is an n-type thermoelectric device and thermoelectric device 118 is a p-type thermoelectric device. When electrode 122 is coupled to a positive potential (relative to the potential coupled to electrode 124), and electrode 120 couples thermoelectric device 116 in series with thermoelectric device 118, electrodes 122 and 124 will have temperature T_{H} and electrode 120 will have a temperature T_{C}, i.e., thermoelectric devices 116 and 118 are coupled electrically in series and thermally in parallel. The lateral thermoelectric device structure illustrated in FIG. 1 may have a figure of merit greater than 1.

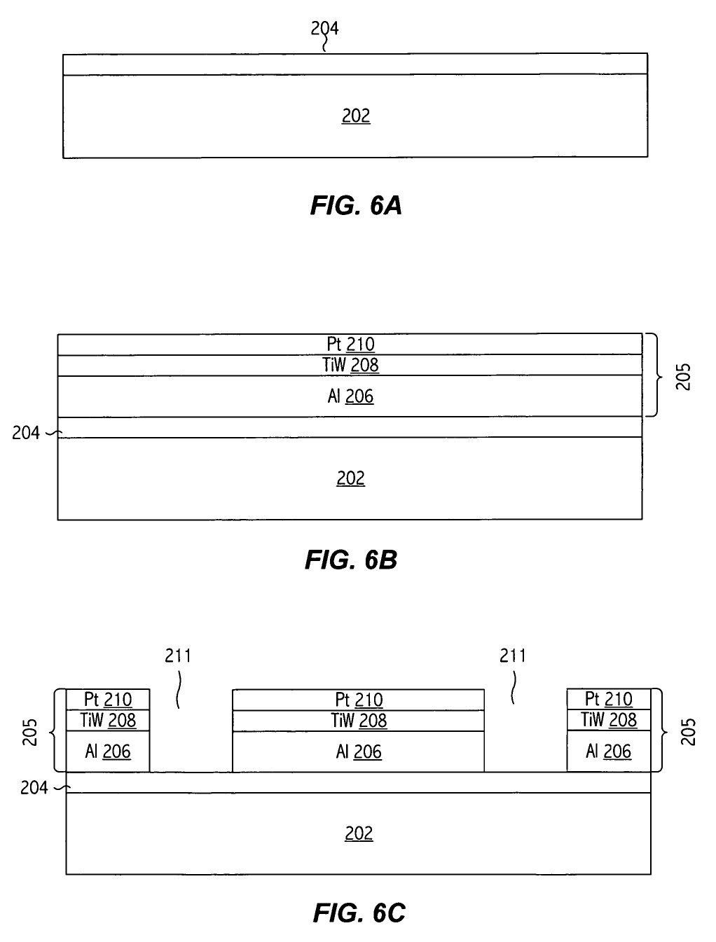

In some cases it may be desirable to reverse the order of the deposition of thermoelectric and electrode materials upon a fabrication substrate. Referring to FIG. 6A, fabrication begins with a substrate 202 of silicon, glass, gallium arsenide, or other suitable material. In some embodiments of the present invention, a low thermal conductivity layer 204 is formed on substrate 202 to reduce heat conduction via the substrate of the device. The thickness of low thermal conductivity layer 204 is generally thinner for materials with lower thermal conductivities. In certain embodiments, low thermal conductivity layer 204 is a layer of SiNₓ—SiO₂ fabricated using low pressure chemical vapor deposition (LPCVD). This high-temperature deposition process yields a high-quality oxynitride layer with excellent stability. In certain embodiments, low thermal conductivity layer 204 is a layer of low-stress silicon nitride. Low-stress Si₃N₄ having residual internal stress less than about 80 MPa makes a good etch stop and may be more easily removable than other materials with low thermal conductivity. Other exemplary low thermal conductivity layer 204 structures may be or include thermal (native) oxide, tetraethylorthosilicate (TEOS) oxide deposited by chemical vapor deposition (CVD) or plasma-enhanced CVD (PECVD), or an oxide deposited by physical vapor deposition (PVD).

Next, a conductive layer 205 is formed atop the low thermal conductivity layer 204, as shown in FIG. 6B. This conductive layer 205 may be comprised of several layers of conductors, adhesion promoters, diffusion barriers, or the like. In some embodiments a layer of aluminum (Al) 206 is deposited first, followed by a layer of titanium-tungsten (TiW) 208 and a layer of platinum (Pt) 210. Conductive layer 205 may be formed using appropriate processing techniques, such as CVD, PVD (including sputtering, thermal or electron-beam (e-beam) evaporation, and pulsed laser deposition (PLD)), self-induced plasma (SIP) PVD, PECVD, electroplating, or any other deposition technique that yields a conductive layer 205 with desired electrical and physical properties. In some embodiments the resulting Al layer is 1 μm thick, while the TiW and Pt layers are much thinner, approximately 10-30 nm and 200 nm, respectively.

The conductive layer 205 may then be patterned using standard semiconductor processing techniques, such as depositing photoresist, exposing the resist through a mask, selectively removing a portion of the conductive layer 205, and removing any remaining resist. Metal layers can be removed by wet or dry etching, while other materials can be removed by techniques such as laser ablation, electron beam writing, or dissolution in solvents. In some embodiments, the Al/TiW/Pt conductive layer 205 is selectively etched by a series of ion etching steps. Using an inductively coupled plasma (ICP), the Pt layer 210 is etched with Ar, the TiW layer 218 with BCl₃, and the Al layer 216 with a mixture of CF₄ and O₂. Regardless of the materials comprising conductive layer 205 or the processes used to selectively remove unwanted portions of it, the removal process preferably stops at the low thermal conductivity layer 204, if present, or the substrate 202.

Alternatively, conductive layer 205 may be patterned using lift-off techniques by depositing photoresist directly on substrate 202 (or low thermal conductivity layer 204, if present), exposing it, selectively removing it, depositing conductive layer 205, and lifting off the remaining photoresist along with unwanted portions of conductive layer 205.

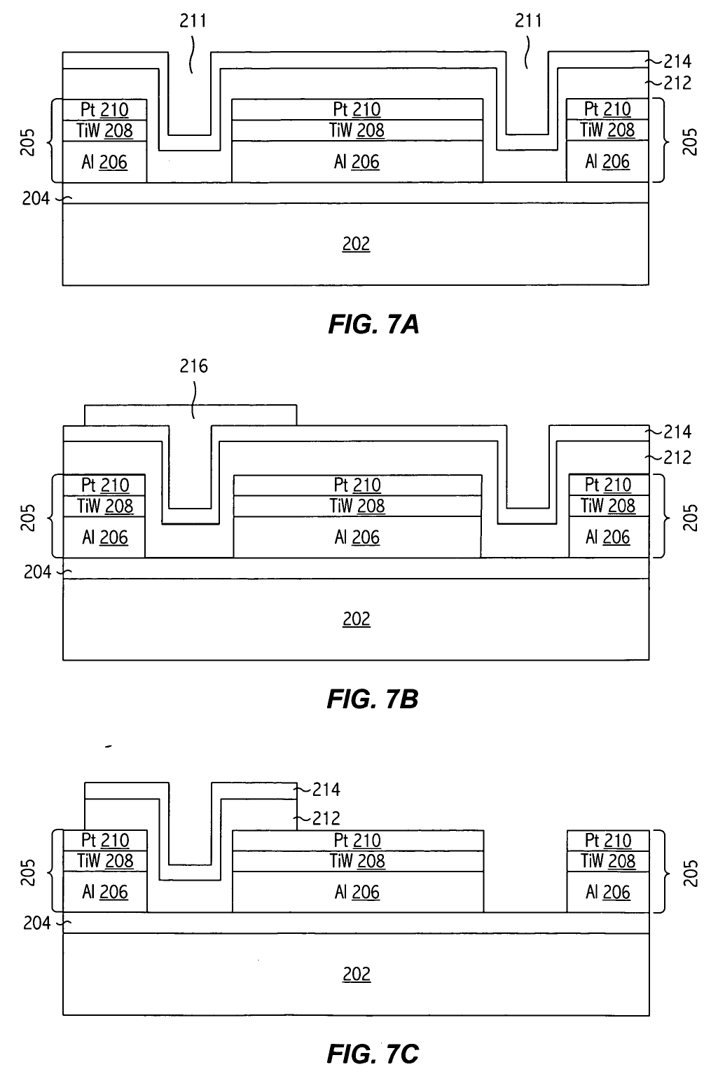

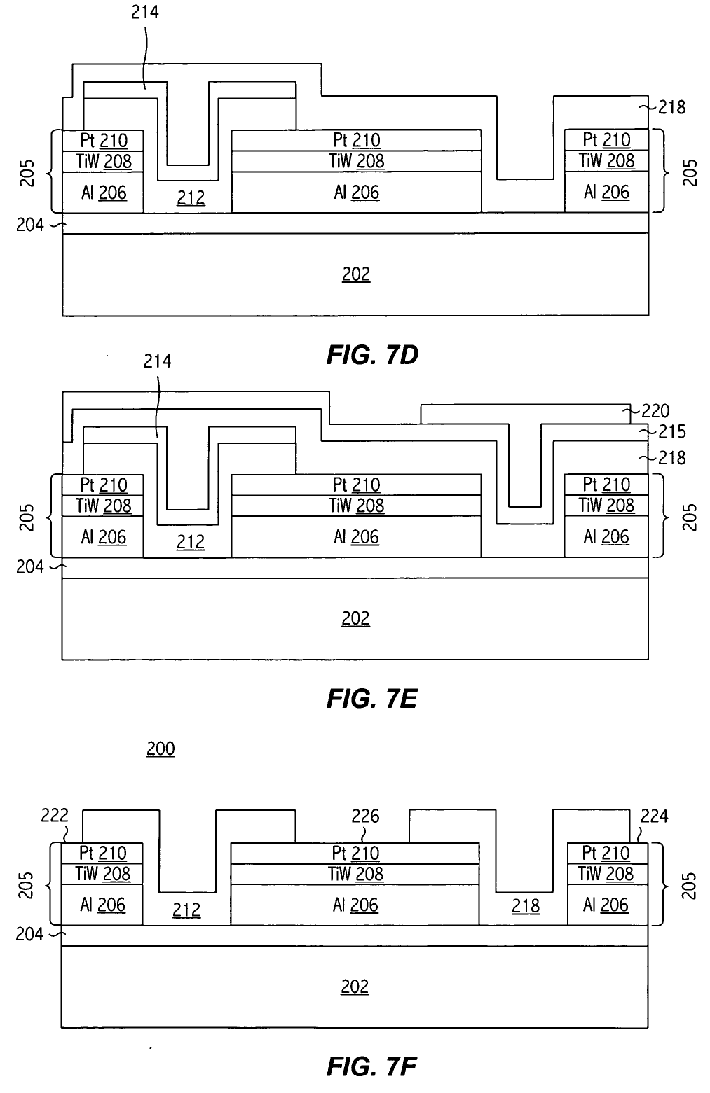

FIG. 6C shows the structure that results after patterning conductive layer 205, with gaps 211 where portions of conductive layer 205 were removed. Referring to FIG. 7A, a layer of thermoelectric material 212 is deposited over the structure of FIG. 6C, covering remaining portions of conductive layer 205 and at least partially filling the gaps 211, and preferably (although not necessarily) making contact with the substrate 202 (or low thermal conductivity layer 204). Thermoelectric material 212 may be deposited by any of the techniques mentioned elsewhere herein, including in the discussion of thermoelectric material 106 in FIG. 3A. In some embodiments, the thermoelectric material 212 is an n-type TE material A thin protective layer 214 (e.g., PECVD oxide layer 214) is deposited on the layer of thermoelectric material 212 to protect it from degradation during subsequent processing, which may include annealing the thermoelectric material 212 to improve its thermal and/or electrical properties from their as-deposited values. Protective layer 214 may be any layer that does not react physically or chemically with thermoelectric material 212 during the process steps for which the two layers are in contact and that protects the thermoelectric material 212 from degradation during those process steps, due to sublimation, impingement by surface contaminants, or contact with photoresist or organic solvents.

At this point, the first layer of thermoelectric material 212 may be annealed, for example, at 350° C. for 30 minutes, if desired. After the annealing step, if any, the oxide-coated structure is patterned using photoresist 216 as seen in FIG. 7B. The protective layer 214 and the thermoelectric material 212 are selectively removed and photoresist 216 is stripped, as seen in FIG. 7C, leaving islands of thermoelectric material 212 in electrical contact with two adjacent features of conductive layer 205 and topped with protective layer 214. The thermoelectric material 212 may be removed using a dry Cl₂ etch, a dry Cl₂+Ar etch, or a wet etch, while the oxides may be removed using a buffered oxide etch (BOE) of dilute HF. One useful wet etch formulation for the bismuth chalcogenides is a solution of ten parts aluminum etch to one part each 70% nitric acid and 39% hydrochloric acid. A useful aluminum etch formulation is H₃PO₄:HNO₃:CH₃COOH:H₂O::16:1:1:2 by volume.

FIG. 7D depicts the structure after a layer of a second thermoelectric material 218 is deposited. Available deposition methods for thermoelectric material 218 are those mentioned elsewhere herein, including for thermoelectric material 106 in FIG. 3A. This second layer of thermoelectric material 218 is preferably of complementary conduction type to thermoelectric material 212. In other words, if thermoelectric material 212 is an n-type semiconductor or semimetal thermoelectric material, then thermoelectric material 218 will be a p-type semiconductor or semimetal thermoelectric material, and vice versa. The deposition of thermoelectric material 218 is followed by deposition of a blanket layer of PECVD oxide 215. At this point, both layers of thermoelectric material 212 and 214 may be annealed, for example, at 300° C. for 2 hours, if desired. Thermoelectric material 218 is then patterned using standard semiconductor processing techniques as before. As shown in FIG. 7E, photoresist 220 protects the portion of oxide 215 covering the thermoelectric material 218 at least partially filling in gaps 211 previously left in conductive layer 205, making electrical contact with conductive layer 205 through the sidewalls of those gaps 211 and/or primarily through the platinum layer 210 forming the top surface of conductive layer 205. The exposed oxide layer 215 and thermoelectric material 218 are then etched as before, protective layer 214 is removed, and photoresist 220 stripped, resulting in the structure of FIG. 7F.

FIG. 7F shows the resulting thermoelectric device structure 200. At this point electrical contact may be made to electrodes 222, 224, and 226 completing the thermoelectric device structure, or the structure may be subjected to subsequent processing, as described below. The lateral spacing between pairs of adjacent electrodes 222, 226, and 226, 224 (i.e., the size of the gaps 211) determines the transport length of the respective thermoelectric device coupled to the electrode pair. Advantageously, this gap dimension (and hence the critical dimension of the resulting thermoelectric element) is determined by a single critical dimension (e.g., a single mask layer and a single associated etch step) and is not sensitive to mask misalignment.

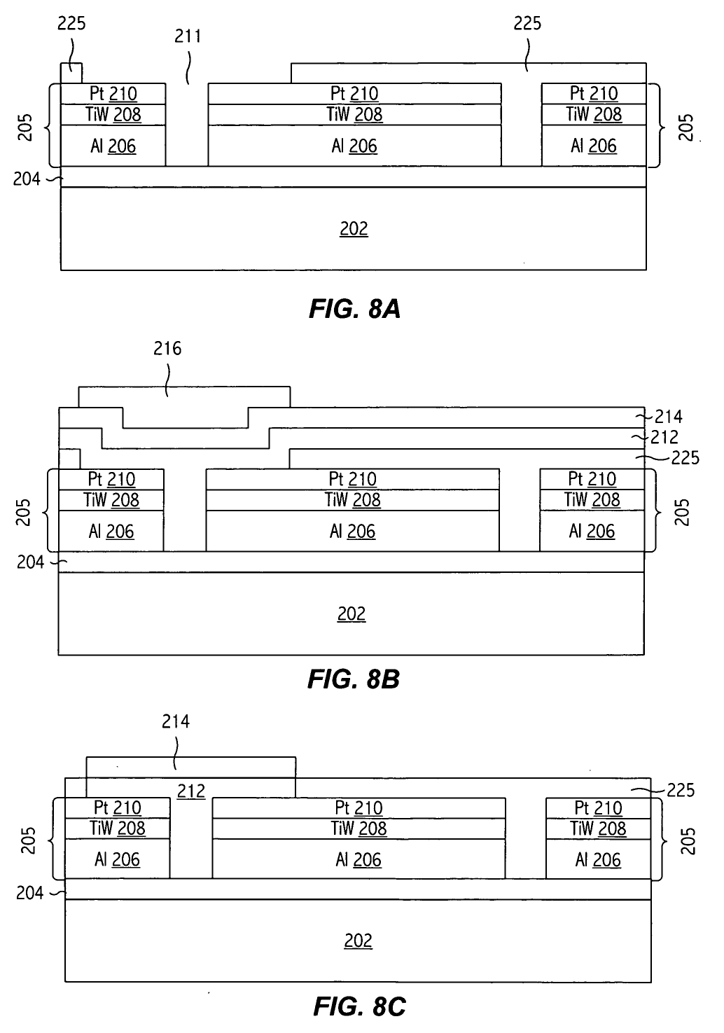

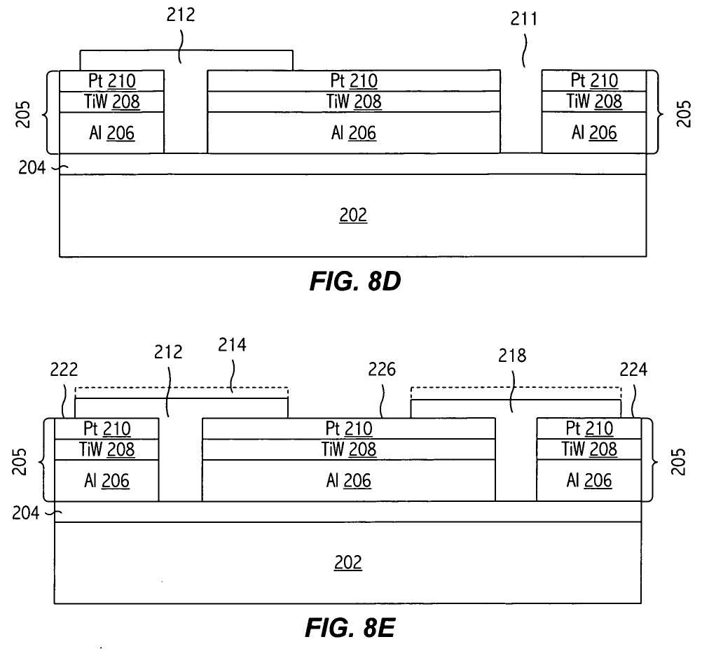

In an alternative method, the substrate 202 is prepared as described above with reference to FIGS. 6A-6C, with a low thermal conductivity layer 204 and a patterned and selectively removed conductive layer 205. A protective layer 225 is deposited, patterned and selectively removed to result in the structure depicted in FIG. 8A. Protective layer 225 may be an oxide, a nitride, or another material that is non-reactive with the substrate 202 (or low thermal conductivity layer 204, if present), conductive layer 205, and thermoelectric material 212. In some embodiments, the protective layer 225 may be a layer of silicon dioxide deposited at fairly low temperatures using PECVD since the aluminum electrodes are already formed. This protective layer may be of lower quality than that of low thermal conductivity layer 204, but it will be removed before final device assembly, making its thermal properties unimportant.

A layer of thermoelectric material 212 is deposited over structure of FIG. 8A, covering remaining portions of conductive layer 205 and at least partially filling the exposed gaps 211. Thermoelectric material 212 may be deposited by any of the techniques mentioned herein. As described previously, a thin protective layer 214 is deposited on top of the layer of thermoelectric material 212 to protect it from degradation during subsequent processing. The protective layer 214 is preferably a low thermal conductivity protective layer. It is contemplated that parylene N may be used as the protective layer 214, although other low thermal conductivity materials described herein may also be used. After an annealing step, if any, the structure is patterned using photoresist 216 as seen in FIG. 8B.

The protective layer 214, the thermoelectric material 212, and protective layer 225 are selectively removed, as seen in FIGS. 8C and 8D, leaving islands of thermoelectric material 212 in electrical contact with conductive layer 205. The thermoelectric material 212 may be removed using a dry Cl₂ etch, a dry Cl₂+Ar etch, or a wet etch as described herein, including with reference to FIG. 7C. Oxides may be removed using a buffered oxide etch (BOE) of dilute HF. Parylene N, if used, may be removed using an oxygen plasma. The low thermal conductivity protective layer 214 may be allowed to remain on the structure.

The processes of FIGS. 8A-8D are repeated for thermoelectric material 218 of opposite conductivity type to that of thermoelectric material 212, resulting in the structure of FIG. 8E. During processing of thermoelectric material 218, the low thermal conductivity protective layer 214 may be left on the structure (as shown by the dashed features 214 in FIG. 8E) rather than stripped. In some cases the structure of FIG. 8E may be coated with a blanket layer of parylene.

At this point electrical contact may be made to electrodes 222, 224, and 226 completing the thermoelectric device structure, or the structure may be subjected to subsequent processing.

In an alternative embodiment of the invention, thermoelectric materials 212 and 218 may bridge the gaps 211 without contacting the substrate 202 or layer 204. Alternatively, gaps 211 may contain a dielectric material other than air, and thermoelectric materials 212 and 218 may be deposited over the dielectric-filled gaps, making contact to conductive layer 205 on either side of the gaps 211 as well as on the surface of layer 205 (i.e., layer 210). In still other embodiments, the thermoelectric materials 212 and 218 may fill the gaps 211 but not significantly extend (or extend at all) over the surface of layer 205.

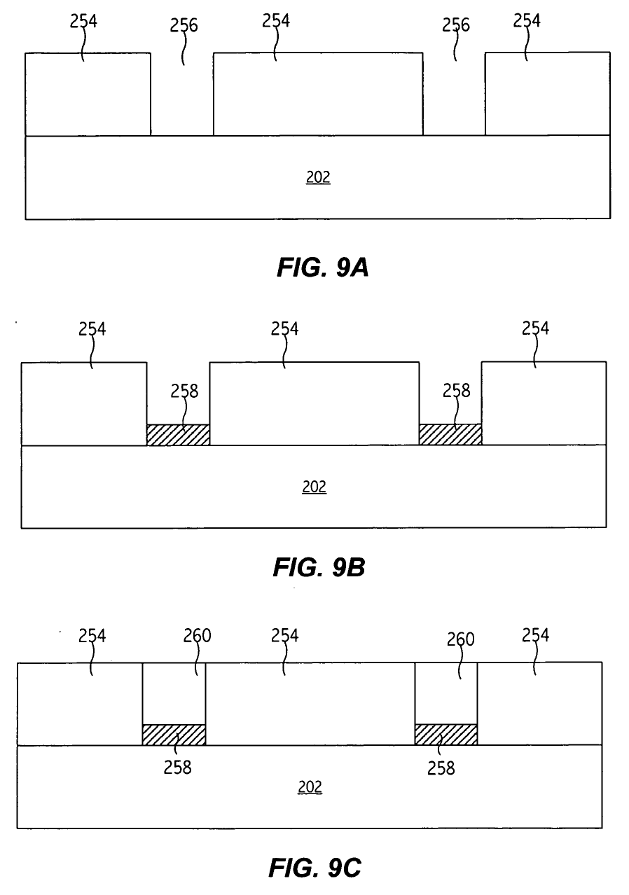

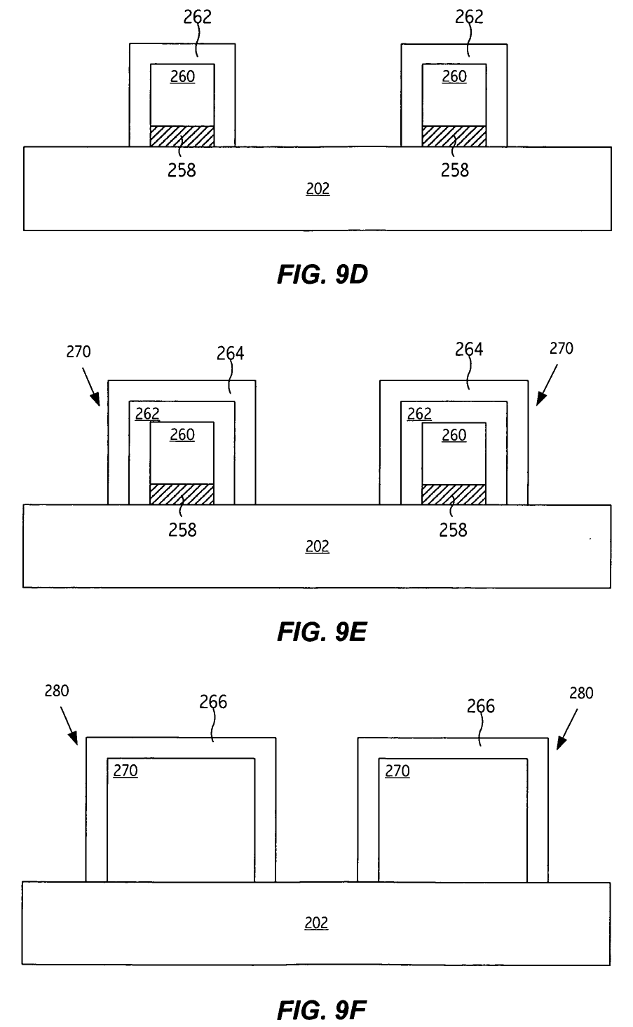

An alternative method of forming a patterned conductive layer is by electroplating. FIG. 9A shows a substrate 202 coated with a blanket layer of silicon dioxide 254 (or alternatively, a photoresist layer) that has been patterned to form pits 256. As seen in FIG. 9B, a seed layer 258 of Ti or Cu is deposited in the pits 256 such as by PVD. A layer 260 of copper is then electroplated onto the structure to a thickness of approximately 1 micron, as shown in FIG. 9C. If the Cu layer 260 overflows the pit 256 the surface may be planarized by chemical mechanical polishing (CMP) techniques. After planarization, if required, the oxide 254 is removed, leaving copper features 260. This structure is then dipped in an electrodeless bath containing dissolved Ni, forming a nickel layer 262 coating the Cu features 260 and its seed 258 completely (FIG. 9D). That structure can then be plated with Pt using a second electrodeless bath (FIG. 9E) to form a platinum layer 264. Electrodes 270 formed by this process can be used instead of the Al/TiW/Pt electrodes of FIGS. 3-8 to define the transport length of thermoelectric elements electrically coupled thereto in lateral thermoelectric devices (i.e., defined by the gap between such electrodes 270).

The conformally electroplated layers 262 and 264 can be plated to a thickness such that the gap between electrodes becomes significantly smaller than lithographically printed. In this way, a smaller gap (e.g., 211 of FIGS. 6C and 8D) defining the transport length of the thermoelectric device in the direction of current flow can be achieved, without using precise lithographic or etching equipment.

Other materials can be used for seed layer 258 and conformally electroplated layers 262 and 264. Seed layers of TaN/Ta/Cu can be deposited by PVD techniques, for example. A layer of TiW may be substituted for the Ni layer 262, followed by the Pt layer 264.

If desired, as shown in FIG. 9F the electrodes 270 of FIG. 9E can be coated with a layer of phonon conduction impeding, or phonon blocking, material 266, for example, indium or a layer of indium topped by a layer of platinum, before processing continues. In fact, the electrodes of FIG. 6C could be so coated before the processing of the thermoelectric device structures continues in FIG. 7A or 8A. The electrodes for other embodiments described herein may be similarly coated.

In all variations of the metal-first process, the effective length of the thermoelectric elements, or their transport lengths in the direction of current flow, is entirely determined by the extent of the gaps between electrodes left by formation of the electrodes. This leads to a relaxation of lithographic tolerances for subsequently deposited layers with respect to processes in which thermoelectric materials are deposited first. Structures in which the electrode material is deposited first may also exhibit lower contact resistance between the thermoelectric materials and the electrode materials.

In some variations of the metal-first process, a single layer of thermoelectric material may be deposited. The complementary type is then formed by conversion of the original thermoelectric material, as described above with reference to FIGS. 4A-4C.

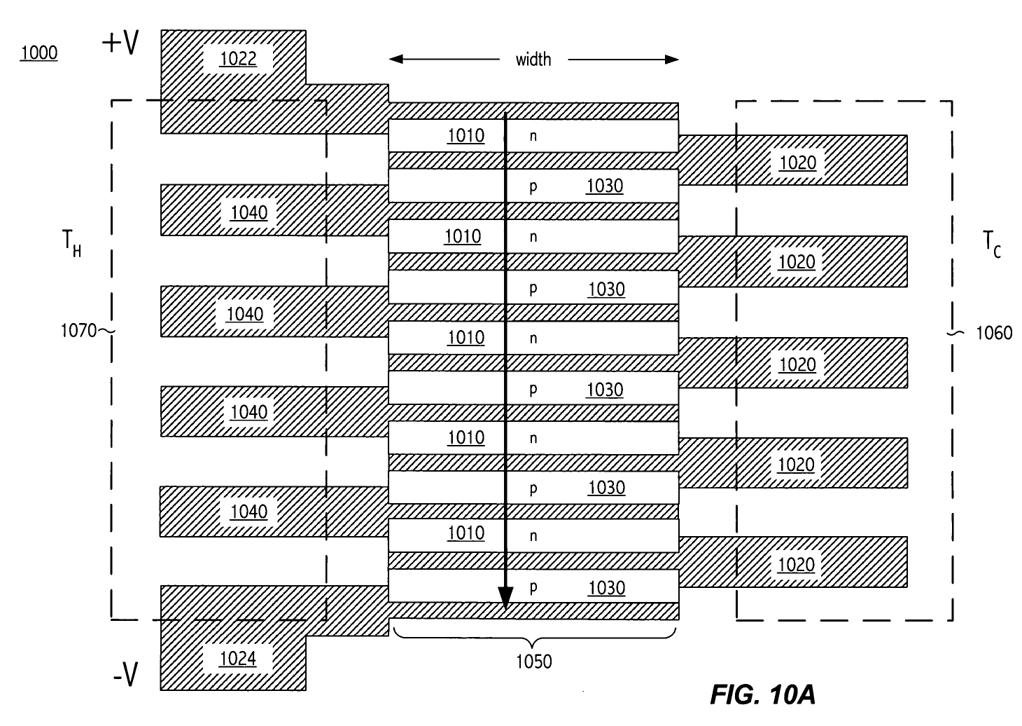

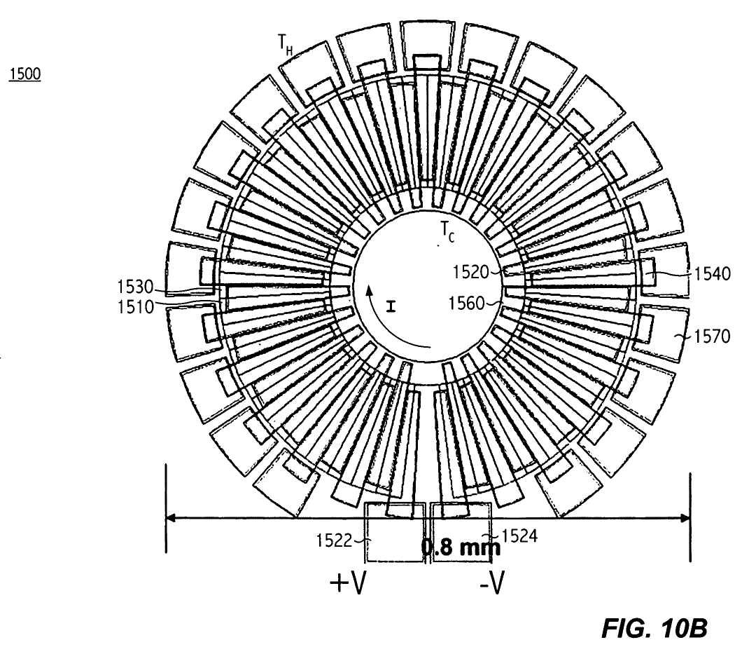

FIG. 10A shows an exemplary lateral thermoelectric device structure 1000. Alternating n-type 1010 and p-type 1030 thermoelectric elements are electrically coupled in a series configuration by electrodes 1020 and 1040 in a thermoelectrically active region 1050. When electrode 1022 is connected to a positive potential relative to the potential coupled to electrode 1024, current flows through the thermoelectric device in the direction indicated. As a result of the current flow, a temperature differential develops across each thermoelectric element 1010, 1030 such that heat flows into the device from the cold side 1060 and flows out of the device at the hot side 1070. Electrodes 1020 are thermally coupled to the cold side of the device, but electrodes 1020 are generally electrically isolated from each other since each is at a slightly different potential (although one such electrode 1020 may be electrically coupled to a thermal pad at the cold side). Similarly, electrodes 1040 are coupled to the hot side, but electrodes 1040 are generally electrically isolated from each other since each is at a slightly different potential (although one such electrode 1040 may be electrically coupled to a thermal pad at the hot side). The length of the thermoelectric device is determined by the gap between the electrodes, as shown. The alternating complementary thermoelectric elements are coupled electrically in series and thermally in parallel. The direction of current flow through lateral thermoelectric device structure 1000 may be reversed, if desired. In this case the thermal differential that develops across the device is also reversed, such that the temperature of electrodes 1020 is higher than the temperature of electrodes 1040.

FIG. 10B depicts an exemplary lateral thermoelectric device structure 1500 having a radial design. Alternating n-type 1510 and p-type 1530 thermoelectric elements are electrically coupled in a series configuration by electrodes 1520 and 1540. When electrode 1522 is connected to a positive potential relative to the potential coupled to electrode 1524, current flows through the thermoelectric device in a clockwise direction, and a temperature differential develops between the interior and exterior of the thermoelectric cooler 1500. Cold electrodes 1520 are thermally coupled to a cold thermal pad 1560. Hot electrodes 1540 are thermally coupled to hot thermal pads 1570. The area and separation of the hot thermal pads 1570 is greater than the area of the cold thermal pad 1560 which facilitates removal of heat from the system. Hot pads 1570 may be coupled to heat sinks, radiators, or other heat transfer systems. Work pieces to be cooled, such as semiconductor lasers, circuits, or LEDs, may be coupled to the cold pad 1560. While the exemplary lateral thermoelectric device structure 1500 forms almost a complete circle, other embodiments forming a partial circle are also contemplated.

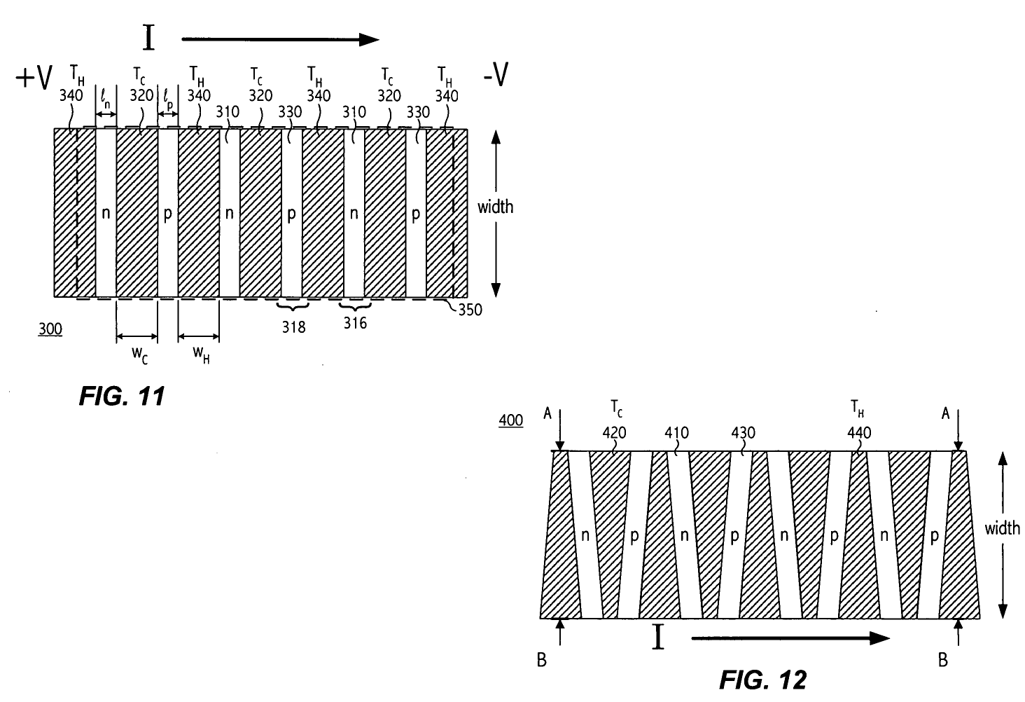

FIGS. 11-17 show several exemplary electrode configurations of particular application to the thermoelectric device structures discussed above. The electrode configurations are described for a given direction of current flow, for clarity, but it is to be understood that, as explained with reference to FIG. 10A, the direction of current flow could be reversed. In that case the temperature differential would also be reversed, and the hot and cold sides of the device would be reversed.

FIG. 11 shows a plan view of a simple rectangular electrode configuration 300. A group of electrodes 320 and a group of electrodes 340 are arranged in an alternating manner, spaced apart laterally. Electrodes of each group may be thought of as individually numbered from that at the highest electrical potential (number 1) to that at the lowest potential (number n for the group of hot electrodes 340 and n−1 for the group of cold electrodes 320). Alternating n-type 310 and p-type 330 thermoelectric elements electrically couple laterally adjacent electrodes in a series configuration within a thermoelectrically active region 350. As seen in the figure, the transport length, lₚ, of p-type thermoelectric device 318, and the transport length, lₙ, of n-type thermoelectric device 316, are determined by the lateral spacing between adjacent electrodes of groups 320 and 340. When current flows in the device 300 in the direction as indicated in FIG. 11, electrodes 340 have a higher temperature than electrodes 320. In this simplest configuration, transport lengths lₙ and lₚ remain constant across the “width” of the thermoelectric device 300, as do the widths w_{H} and w_{C} of the hot 340 and cold 320 electrodes.

As depicted in FIG. 12, the width of the electrodes need not be constant. FIG. 12 shows the top view of a thermoelectric device 400 with groups of tapered electrodes 420 and 440 that electrically couple alternating n-type (410) and p-type (430) thermoelectric elements. At the edge AA of the thermoelectricly active region, the width w_{C} of the cold electrode 420 is greater than the width w_{H} of the hot electrode 440. At the edge BB, the width w_{C} of the cold electrode 420 is less than the width W_{H} of the hot electrode 440. In this example, the transport lengths lₙ and lₚ of thermoelectric elements 410 and 430 remain constant across the “length” of each thermoelectric element (i.e., across the “width” of each thermoelectric device). In operation, a temperature profile develops within the thermoelectric device 400 with isotherms that follow contours more like those of tapered electrodes 420 and 440 than of rectangular electrodes. Tapering the electrodes, then, allows for more efficient use of conductors, since the corners of electrodes 320 and 340, for example, do not participate substantially in thermal transport. It also allows for denser packing of thermoelectric devices while maintaining a constant effective element transport length (lₙ or lₚ).

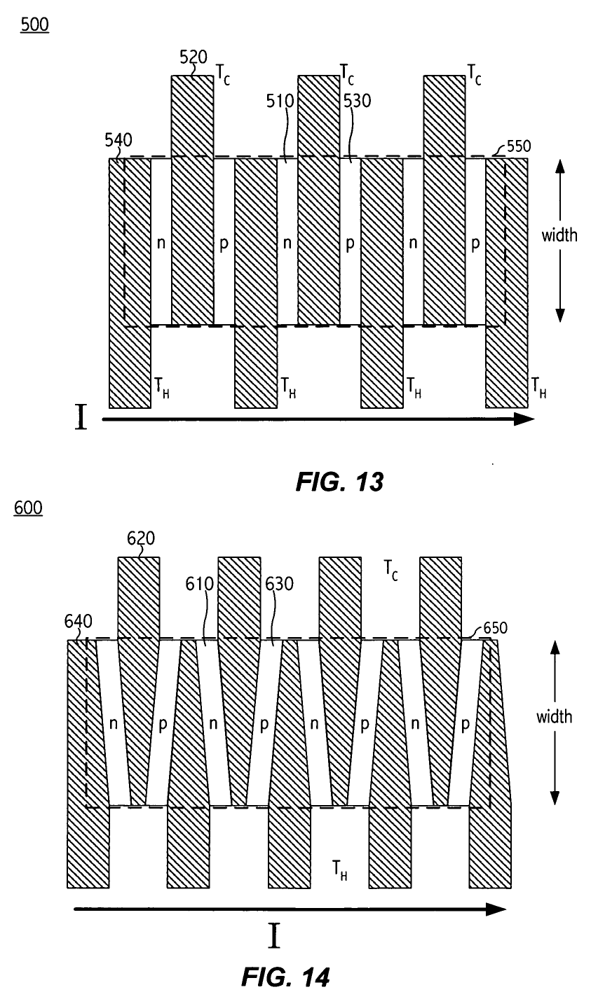

Although FIGS. 11 and 12 show the thermoelectric materials having the same extent as the electrode materials this need not be the case, as depicted schematically in FIGS. 13 and 14. FIG. 13 shows a thermoelectric device 500 similar to that of FIG. 11, but with the alternating groups of electrodes 520 and 540 extending outside the region 550 containing thermoelectric elements 510 and 530. The width of the device is determined by the extent of thermoelectric material. In this example, interdigitated groups of cold electrodes 520 and hot electrodes 540 are displaced asymmetrically with respect to the thermoelectrically active region 550. FIG. 14 shows a thermoelectric device 600 with an electrode configuration corresponding to that of the device of FIG. 12, with interdigitated groups of electrodes 620 and 640 extending outside the region 650 containing thermoelectric elements 610 and 630. Such interdigitated electrodes alternately extend into the thermoelectricly active region from opposite sides thereof, and may also be viewed as interleaved electrodes.

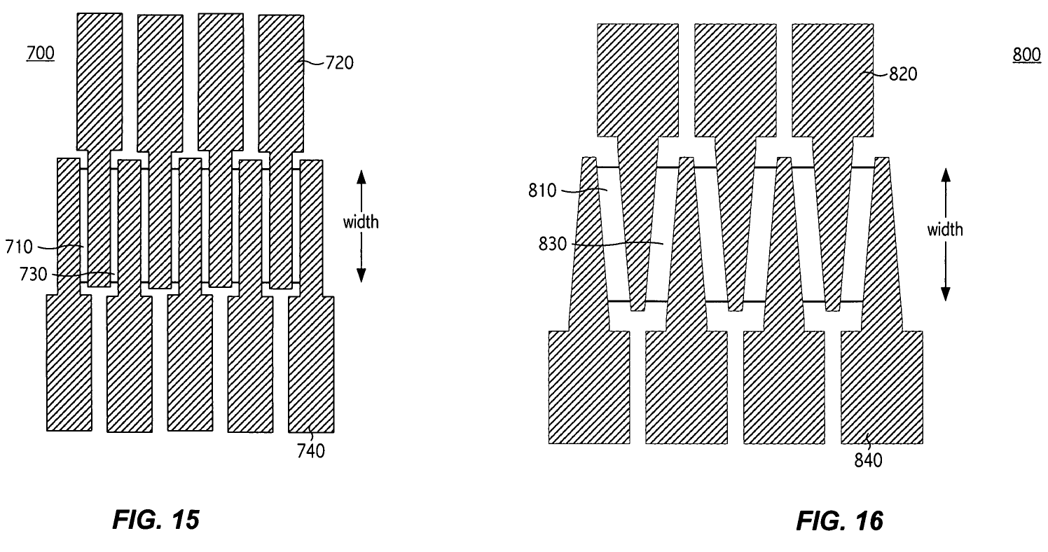

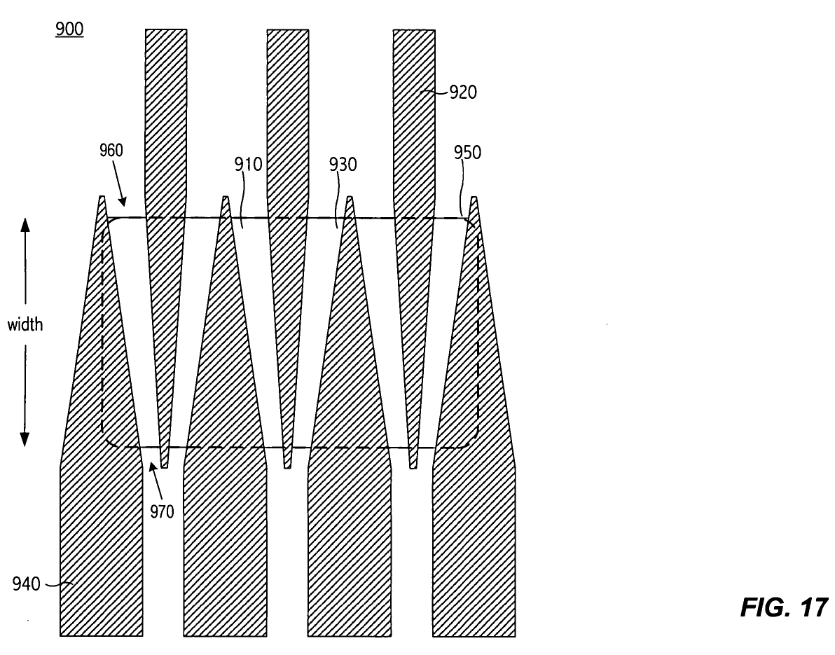

FIGS. 15 and 16 show alternative electrode configurations according some embodiments of the present invention. In FIG. 15 the interdigitated electrodes 720, 740 of thermoelectric device 700 are narrower in the region containing thermoelectric elements 710 and 730 than outside it, but their transport lengths remain constant within this region (i.e., the electrode gap is constant in width within this region). In FIG. 16 the interdigitated electrodes 820, 840 of thermoelectric device 800 are narrower in the region containing thermoelectric elements 810 and 830 than outside it, and they are tapered within this region.

FIG. 17 depicts a thermoelectric device 900 having tapered interdigitated electrodes wherein the transport length of thermoelectric elements 910, 930 as determined by the spacing of electrodes 920 and 940 varies in the region 950 containing thermoelectric elements 910 and 930, being narrower at the hot side 970 of the device 900 than at the cold side 960.

In some cases it may be desirable to subject the thermoelectric device structures of FIGS. 7F and 8E to further processing. In particular it may be desirable to remove the original fabrication substrate 102 or 202, and the low thermal conductivity layer 104 or 204, if present. When the original substrate, with or without overlayers, is to be removed before deployment of the final device or structure, the criteria for selecting a substrate are relaxed considerably. The properties of the substrate with respect to suitability in the final device, such as thermal conductivity, electrical conductivity, and optical properties such as dielectric constant or transparency, need no longer inform the choice of substrate, which can then be chosen for its suitability purely as a base or support structure for forming the device structures. Often these substrates are prepared by depositing etch stop layers on both sides of the substrate before the fabrication steps described with respect to FIGS. 3-8 are undertaken.

A fabrication substrate, with or without overlayers that form no part of the final structure, that is removed (or is destined to be removed) before the final deployment of the device structure, may be referred to as a “sacrificial substrate” and it is understood that all of the layers to be so removed, including protective overlayers deposited on the original substrate, are included in this term. It should also be recalled that these subsequent processing steps do not change the fundamentally monolithic nature of the methods for forming the complementary thermoelectric materials and other layers on a common substrate, regardless of the number of “substrates” used or consumed in the processing of the final device structure, or whether the thermoelectric device is subsequently transferred to a carrier substrate and the original fabrication substrate removed.

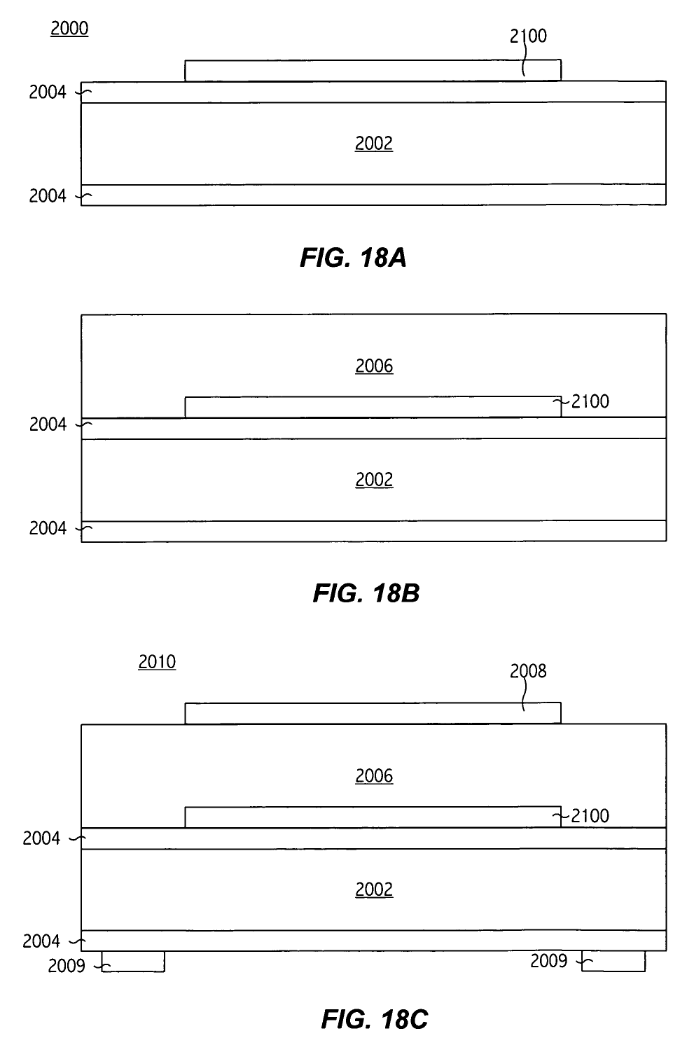

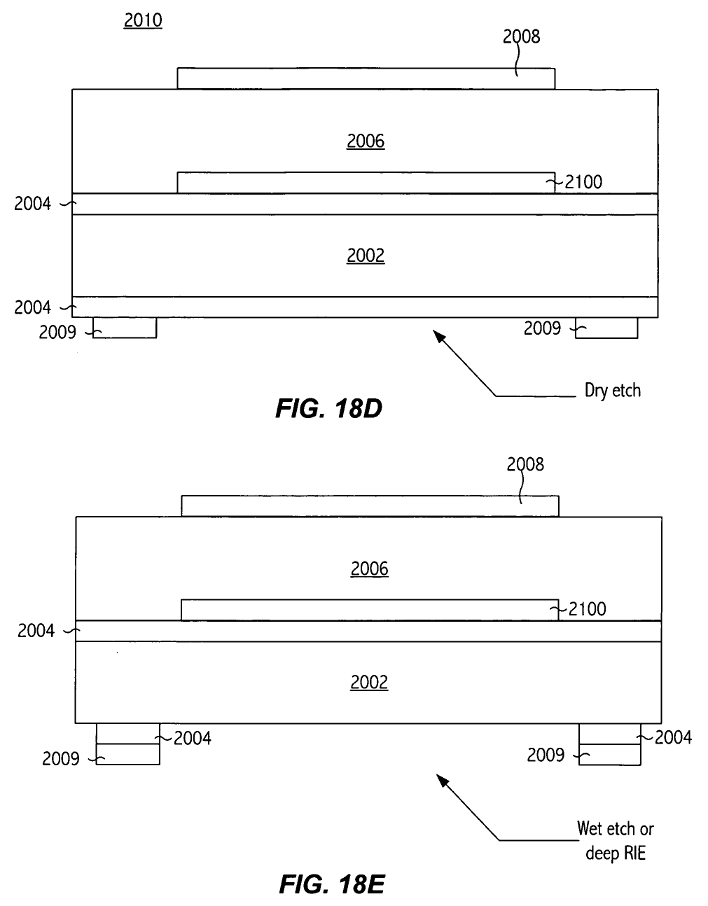

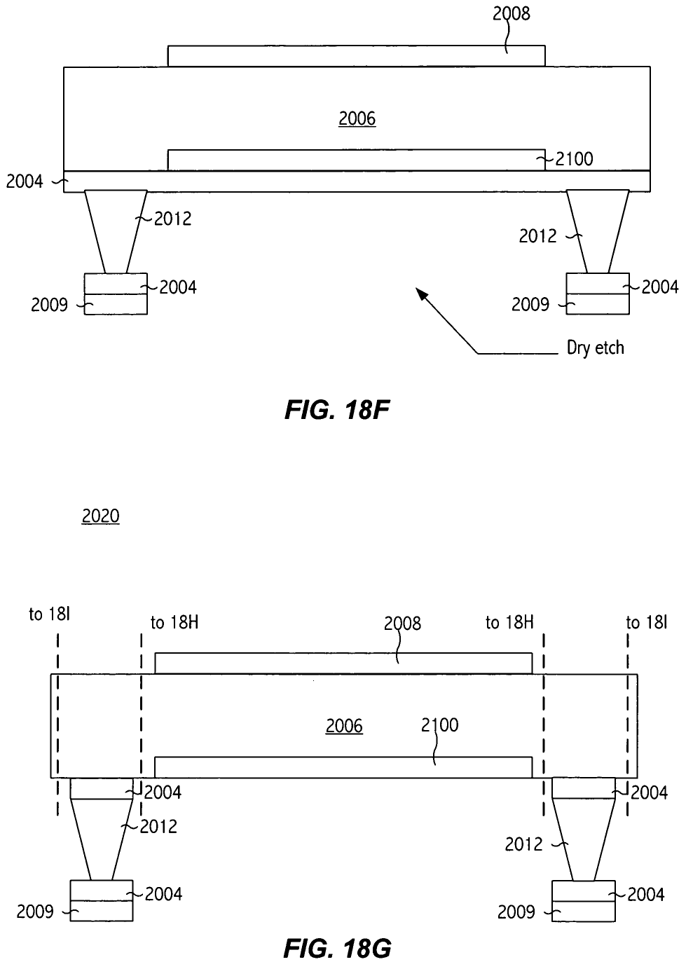

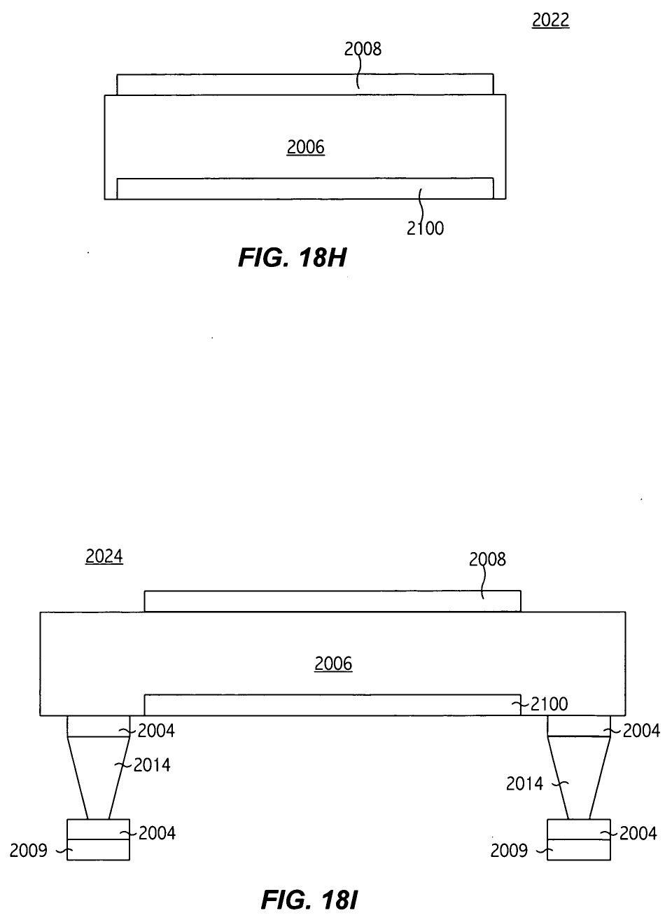

FIGS. 18 through 20 show various methods for removal of the sacrificial substrate. FIG. 18A shows a thermoelectric device structure 2000, comprising active thermoelectric device layers 2100 (including, for example, a thermoelectric device comprising thermoelectric elements and electrodes as described herein) on a sacrificial substrate 2002 that may have an etch stop layer 2004 deposited on one or both sides. Thermoelectric device layers 2100 have been formed by selective deposition and removal of layers of material, so some areas of the sacrificial substrate 2002 may not be covered, as shown schematically in FIG. 18A. Such an etch stop layer for silicon substrates may include, for example, an oxynitride layer deposited using LPCVD or a low-stress silicon nitride layer. As depicted in FIG. 18B, a thick protective layer 2006, up to about 2 mils (0.002 inches, or about 50 microns), is deposited on thermoelectric structure 2000, filling in any surface irregularities left by processing of the thermoelectric device layers 2100. This protective coating 2006 may include a (relatively) low-melting point solid, such as parylene C, or a (relatively) high melting point solid, such as silicon dioxide, silicon nitride, or silicon oxynitride, depending on the subsequent processing steps envisioned for the structure. In addition, such protective layer may include polytetrafluoroethylene, an aerogel, or a low thermal conductivity material. The fluoropolymer polytetrafluoroethylene (PTFE) is also sometimes referred to as Teflon®, which is a registered trademark of DuPont, located in Wilmington, Del. As used herein, “fluoropolymers” also includes amorphous fluoropolymers, such as the materials commercially available as Teflon® AF 1600 and Teflon® AF 2400, which may also be advantageously used. Protective layer 2006 should not undergo undesirable reactions with any of the materials so far deposited, or with those anticipated to be deposited in contact with it, at the processing and use temperatures planned and in the operating environments envisioned. In certain embodiments, this thick protective layer 2006 is parylene N (polyparaxylylene) having a thickness of about 25-50 microns. In some embodiments, the protective layer 2006 may be at least 5 microns thick and still be effective as a low thermal conductivity protective layer.

“Parylene” is a generic term for a series of polymers based on para-xylylene and its substituted derivatives. The parylenes have low dielectric constants, good thermal stability, and low thermal conductivity. Parylene N, or poly(para-xylylene), has a relatively higher melting point than parylene C, or poly(monochloro-para-xylylene), and parylene D, or poly(dichloro-para-xylylene). Parylene F, also called parylene AF-4, is poly(tetrafluoro-para-xylylene), and has a lower dielectric constant and higher thermal stability than parylene N.

“Fluoropolymers” are exemplified by the Teflon® family of polymers. The original Teflon® brand fluorocarbon polymer is, as noted elsewhere in the description, polytetrafluoroethylene or PTFE. Other members of the family include FEP (a copolymer of tetrafluoroethylene and hexafluoropropylene), ETFE (a copolymer of ethylene and tetrafluoroethylene), and PFA (perfluoroalkoxy fluorocarbon). Amorphous fluoropolymers, such as DuPont's Teflon® AF 1600 and Teflon® AF 2400, are amorphous, as opposed to semicrystalline or crystalline. Their optical clarity and mechanical properties are similar to those of other amorphous polymers, while their electrical, thermal, and chemical properties resemble those of semicrystalline or crystalline fluoropolymers.

Silica (SiO₂), alumina (Al₂O₃), or titania (TiO₂) aerogels may be used, and each may be formed by common processes such as spinning on a precursor solution, catalyzing the sol-gel reaction, and driving out remaining volatiles and water by supercritical drying at about 100° C. in a carbon dioxide atmosphere. This aerogel application process may be repeated until the thermal insulation layer is of the desired thickness.

At this point layers of metal may be deposited on one or both sides of the composite structure, and the metal layer(s) subsequently patterned as desired using standard processing techniques, as shown in FIG. 18C. One method of depositing conductive layers 2008 is to electroplate or electrodeposit layers of Cu/Ni/Au on the front side of the structure. On the back side of the structure a hard mask layer 2009, e.g. Cr, Ti, or TiW, is deposited. This composite metal layer 2008 and hard mask layer 2009 can be patterned using front and back side alignment (dual-side alignment) or infrared (1R) alignment. Generally the front side metallization area corresponds to the area of individual thermoelectric devices. The resulting composite structure is then affixed to a support with the sacrificial substrate 2002 exposed to undergo dry or wet chemical etching to remove those portions of sacrificial substrate 2002 not protected by the hard mask features 2009. In certain embodiments, as shown in FIGS. 18D-18F, the intermediate structure 2010 is subjected to a dry etch to remove the oxynitride or low-stress nitride, and then to deep reactive ion etching (RIE) or a wet chemical etch in KOH to remove the silicon substrate. The choice of material for the etch stop layer 2009 depends on the sacrificial substrate removal method, with Cr making a better hard mask for KOH (wet) processing, and Ti or TiW for deep RIE. The KOH etch is less effective against certain atomic planes in single-crystal silicon, and leaves angled pylons or legs 2012 whose sides are defined by the alignment of the atomic planes of single-crystal silicon in the sacrificial substrate 2002. The KOH etch is virtually entirely ineffective against the nitride layer 2004 (thus its designation “etch stop layer”), so the risk of overetching, or etching through to the active device structures, is mitigated. An alternate process is to time the KOH etch very finely, or to stop the etch bath at intermediate stages to check for breakthrough, so that the etch stop layer 2004 may be omitted. If desired, etch stop layer 2004 may be removed by dry etching, as shown in FIG. 18G.

At this stage the wafer containing thermoelectric structures 2020 may be ready for final deployment, in which case individual device structures may be separated by laser ablation, sawing, cleaving, or other separation methods. In some cases, particularly when the protective layer is a parylene, the etch stop layers 2004 may be removed and the separation accomplished by laser ablation. In some cases it may be desirable to discard the angled pylons 2012 resulting in the structure 2022 of FIG. 18H. In others it may be desirable to use the angled pylons or legs 2012 along with their associated layers 2004, 2009 (when present), for example as cold fingers or support ribs 2014, in the final device structure, in which case the thermoelectric device structures 2020 would be separated from each other but not from their respective pylons 2012, resulting in structure 2024 of FIG. 181. In both FIG. 18H and FIG. 181, the thermoelectric device layers 2100 may be viewed as being supported by a supporting layer 2006 disposed upon a supporting base 2008.

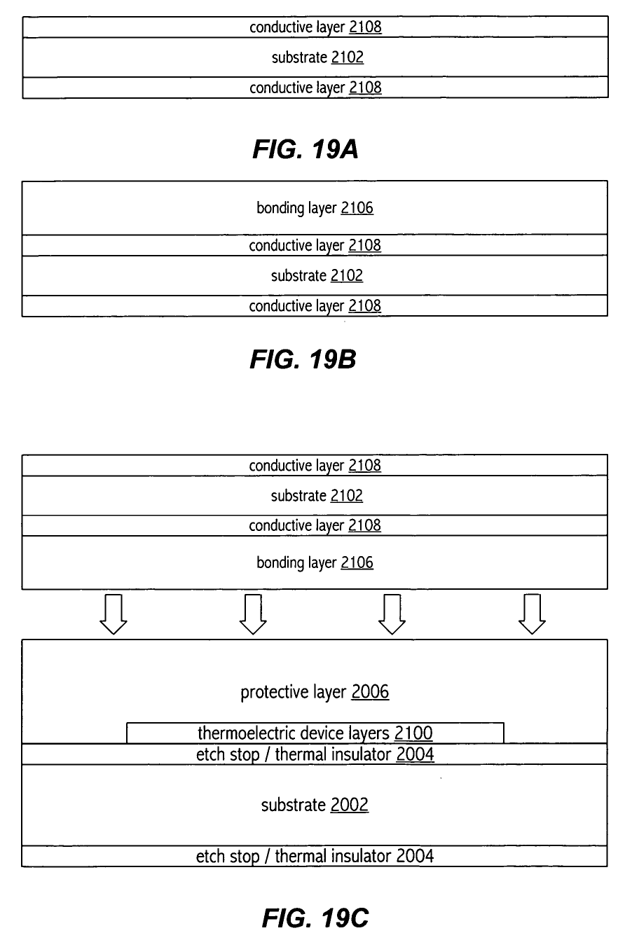

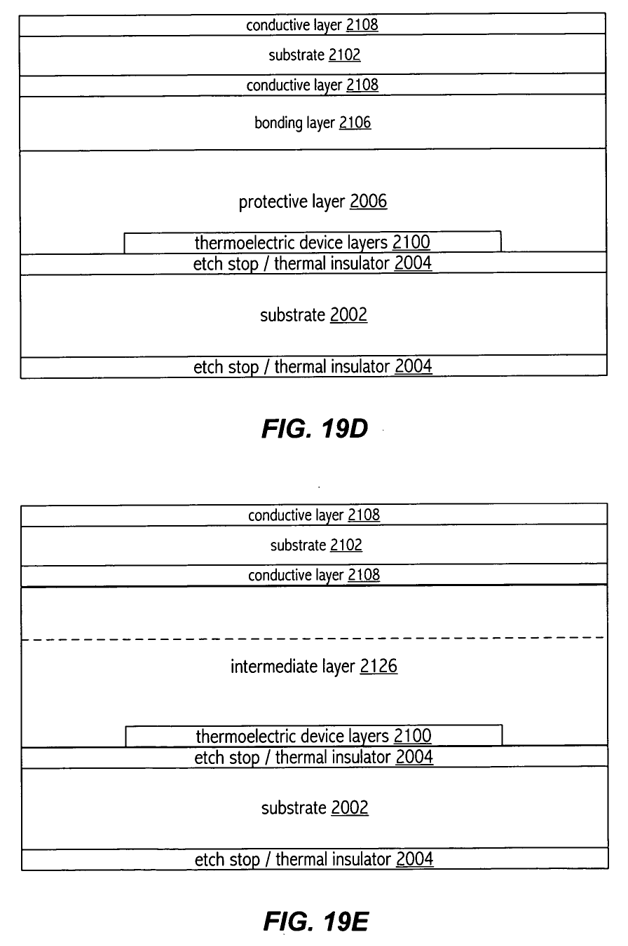

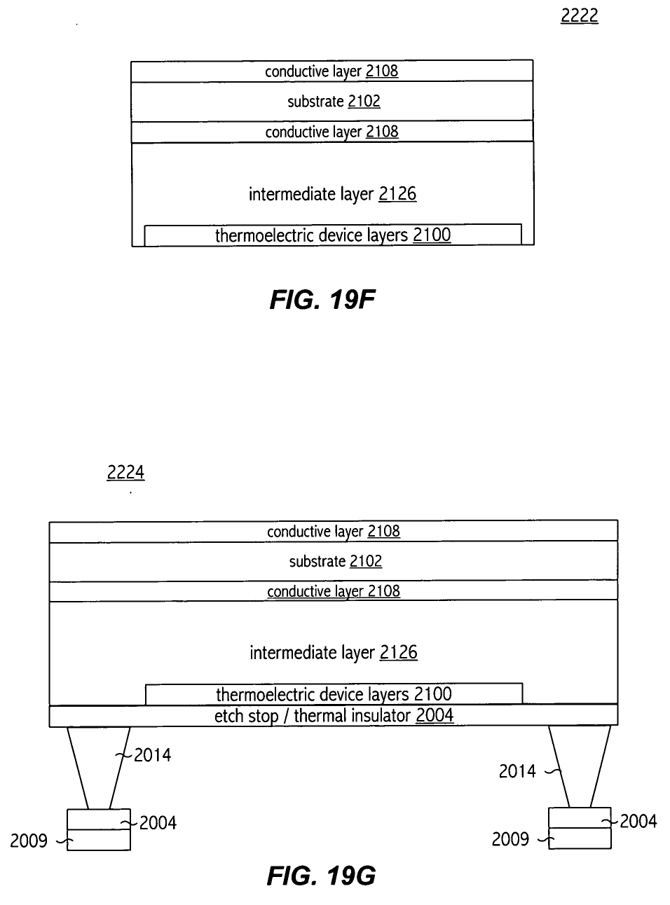

FIGS. 19A-19G show an alternate method of forming a final device structure from the thermoelectric structure 2000 of FIG. 18A. A second substrate 2102 is prepared by thinning and a conductive layer 2108 deposited on both sides, as in FIG. 19A. Thinning may be done by CMP techniques, or a thin substrate may be purchased from the manufacturer. Conductive layers 2108 may be deposited using processes described elsewhere herein. One process for depositing conductive layers 2108 is electroplating. Conductive layers 2108 may be single layers or composite structures, as described previously. A bonding layer 2106 is then deposited as in FIG. 19B. This bonding layer 2106 may be a semisolid, such as wax, a (relatively) low melting point polymer, such as parylene C, a (relatively) high melting point polymer such as parylene N, a metal, or any other material that can be bonded to the protected surface of the protected thermoelectric structure of FIG. 18B (or similar structures) and that will survive subsequent processing steps without degrading the properties of the thermoelectric device. In certain embodiments, the thermoelectric structure 2000 is coated with a protective layer 2006 of parylene C, substrate 2102 is coated with layers 2108 of metal on both sides, and one metallized side of the substrate 2102 is coated with a bonding layer 2106 of parylene N. Protectively coated sides of the two structures are mated and bonded, as shown in FIGS. 19C and 19D. As seen in FIG. 19E this process fuses the bonding layer 2106 and protective layer 2006 into an intermediate layer 2126. Subsequent processing to remove the sacrificial substrate 2002 proceeds as above, resulting in the device structure 2222 of FIG. 19F or the device structure 2224 of FIG. 19G.

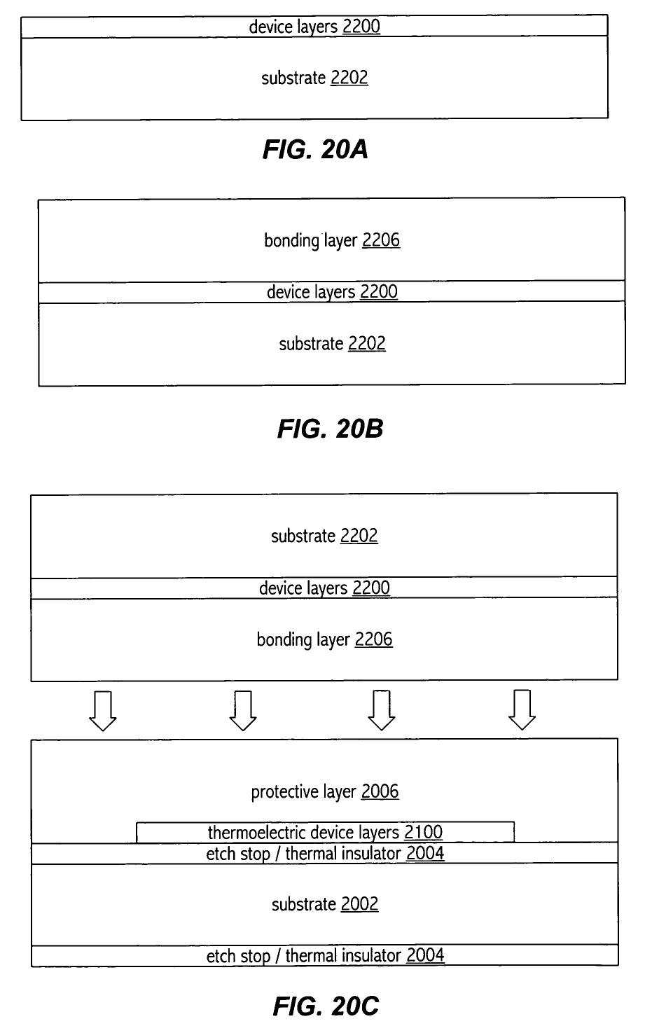

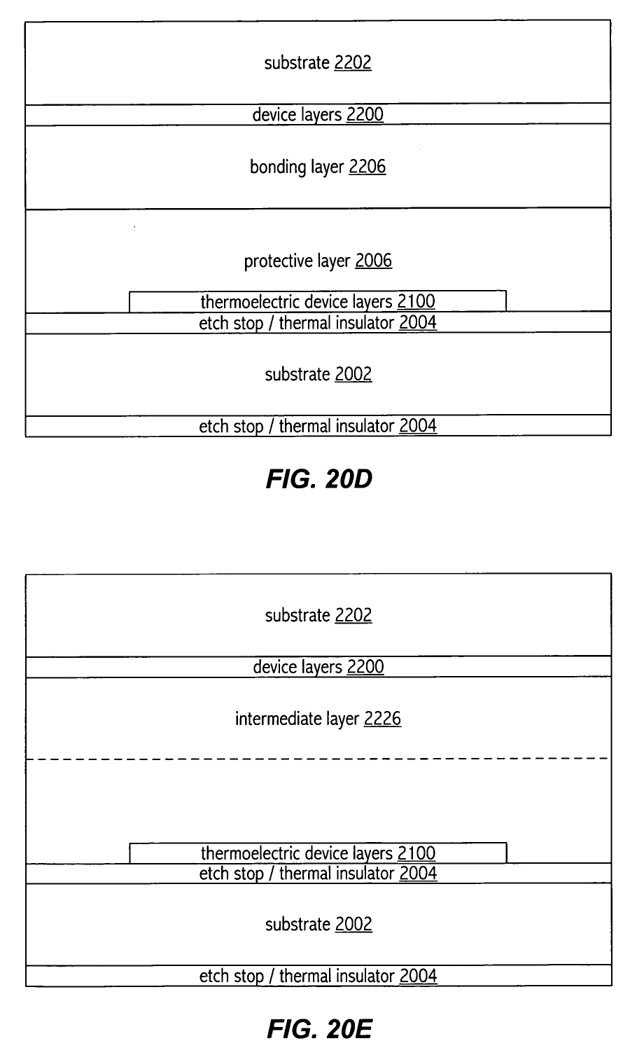

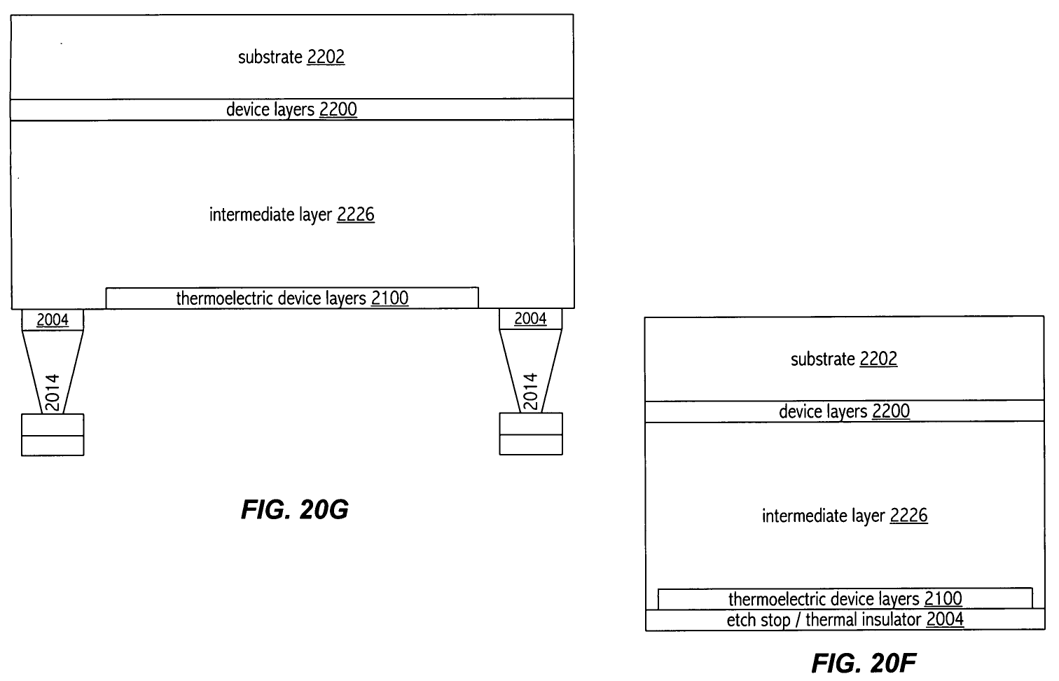

FIG. 20 shows yet another method of forming a final device structure from the thermoelectric structure 2000 of FIG. 18A or similar structure. A second composite of active device layers 2200 is formed on a second substrate 2202 as shown in FIG. 20A. These active device layers 2200 may contain thermoelectric devices, semiconductor devices, memory elements, integrated circuits, and the like. Substrate 2202 likewise may be any substrate material compatible with active device layers 2200. As depicted in FIG. 20B, a bonding layer 2206 is deposited atop active device layers 2200 (and any intermediate protective layers that may be present). Again the two structures are mated and bonded with protective layer 2006 of thermoelectric structure 2000 fusing with bonding layer 2206 of the second device structure as in FIGS. 20C-20E to form an intermediate layer 2226. Examples of resulting completed structures are shown schematically in FIGS. 20F and 20G.

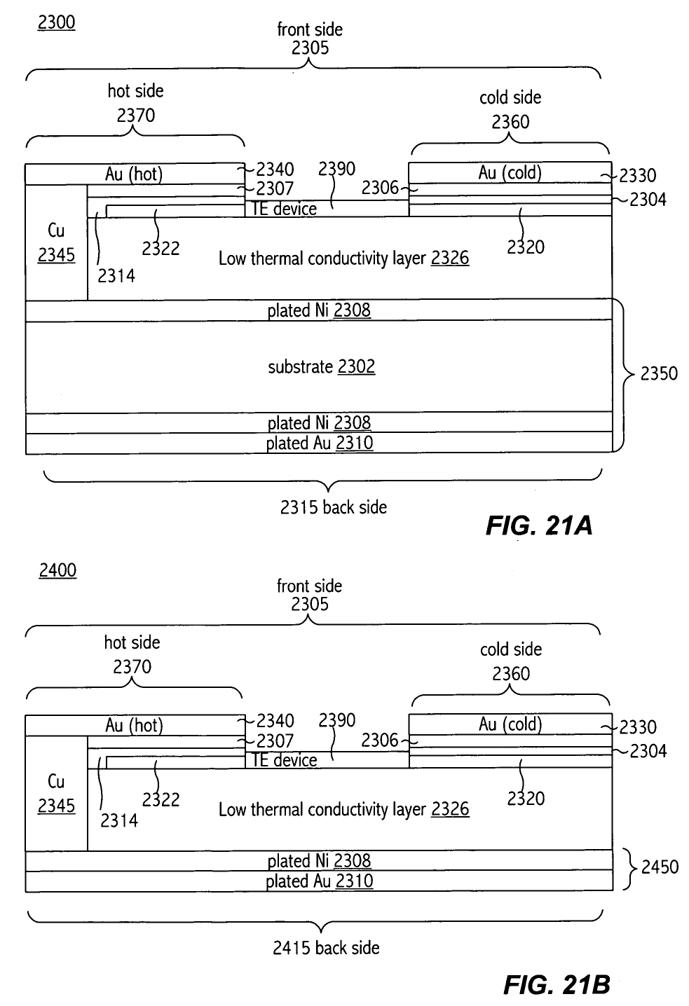

FIG. 21A depicts a vertical heat rejection structure 2300 incorporating a lateral thermoelectric device and which, in certain embodiments, utilizes a lateral thermoelectric device as described elsewhere herein. In particular, such lateral devices incorporating a very low thermal conductivity supporting structure, such as a parylene layer, are contemplated in such a vertical configuration. As depicted, a lateral thermoelectric device 2390 is electrically coupled to electrodes 2320, 2322 and is disposed upon a two-layer supporting structure. In certain embodiments, the upper layer 2326 of the supporting structure, upon which the lateral thermoelectric device 2390 is disposed, is a parylene layer which is chosen for its low thermal conductivity. This upper layer 2326 provides thermal isolation from a lower layer 2350 of the supporting structure, which here is depicted as a substrate, such as a thin silicon substrate 2302, having a layer of plated nickel 2308 on both upper and lower surfaces thereof, and upon which the lower nickel layer 2308 is subsequently plated with an additional gold layer 2310. In certain embodiments, the upper “layer” 2326 of the supporting structure may include one or more different layers, and the lower “layer” 2350 may be viewed as a supporting base for the lateral thermoelectric device 2390 (which base may also include one or more layers or structures).

During operation, a temperature differential develops across thermoelectric device 2390 creating a hot side 2370 and a cold side 2360. The upper layer 2326 of the supporting structure is removed from part of the hot side 2370 of the thermoelectric device 2390 by, for example, laser ablation, exposing the plated nickel layer 2308. Copper is plated onto the exposed region, forming a plug 2345 in thermal contact with the supporting “base” 2350 and thus to the back side 2315 (i.e., the “bottom”) of the vertical heat rejection structure 2300, forming a thermally conducting path between the front side 2305 (i.e., the “top”) and the back side 2315 of the structure 2300. A layer 2310 of gold is then plated onto both sides of vertical heat rejection structure 2300. Thermal contacts, or pads, 2330, 2340 for the thermoelectric device 2390 are then formed on the front side 2305 of the vertical heat rejection structure 2300 disposed upon respective earlier-formed metal layer features 2306, 2307. During operation, heat flowing out of the hot side 2370 of the lateral thermoelectric device 2390 is coupled through a dielectric layer 2314 to the metal feature 2307 and hot pad 2340, through the copper plug 2345, through the layer 2350, and to the back side 2315 of the vertical structure. The large surface area of the gold layer 2310 on the back side 2315, and the relatively larger thermal conductivity of the supporting base 2350 compared to the upper supporting layer 2326 of the supporting structure, affords favorable heat dissipation to a structure such as a heat sink, a case, or other suitable ambient heat exchanger (not shown). A device, such as an integrated circuit die, a laser diode, a photodiode, etc., may be mounted on the cold pad 2330 and cooled by a vertical heat rejection structure as depicted, even though such a structure incorporates a lateral thermoelectric device.

In some embodiments, the upper supporting layer 2326 may include a material having a thermal conductivity of approximately 0.02 W/m-K, e.g., an aerogel, which may be 20 μm thick. In some embodiments, the upper supporting layer 2326 may include one or more parylene layers using one or more of the parylene materials described above. In various embodiments, the upper supporting layer 2326 may preferably be 5-50 μm thick. In some embodiments, the substrate 2302 represents a carrier substrate and the layer 2326 represents an intermediate layer formed by bonding two protective layers together (as described elsewhere herein). In some other embodiments, the substrate 2302 represents a fabrication substrate and the thermoelectric device 2390 is formed directly on the supporting layer 2326, which is formed on the fabrication substrate.

In other embodiments, the vertical thermally conductive path from the hot side to the lower layer of the supporting structure may be fashioned in a variety of other ways. A thermally conductive but electrically insulating material may be used in place of the copper plug 2345, in which case such a thermally conductive plug may contact each of the hot side electrodes of the thermoelectric device 2390 (unlike the copper plug 2345 shown, which is depicted as electrically and thermally contacting a metal plate, i.e. a thermal pad, overlying the hot electrodes, and is thus thermally coupled to such hot electrodes by way of a relatively thin dielectric layer 2314, without making electrical contact to such hot electrodes). In some embodiments, a thermally conductive path may be formed below the hot electrodes 2322 rather than to the side.

FIG. 21B shows an alternate embodiment of a vertical heat rejection structure 2400. Here, the lower (i.e., second) supporting structure 2450 (i.e., the supporting base) of vertical heat rejection structure 2400 is formed by depositing a Ni layer 2308 directly onto insulating supporting structure 2326, as described, for example, with reference to FIG. 18C. Processing proceeds as for vertical heat rejection structure 2300 of FIG. 21A.

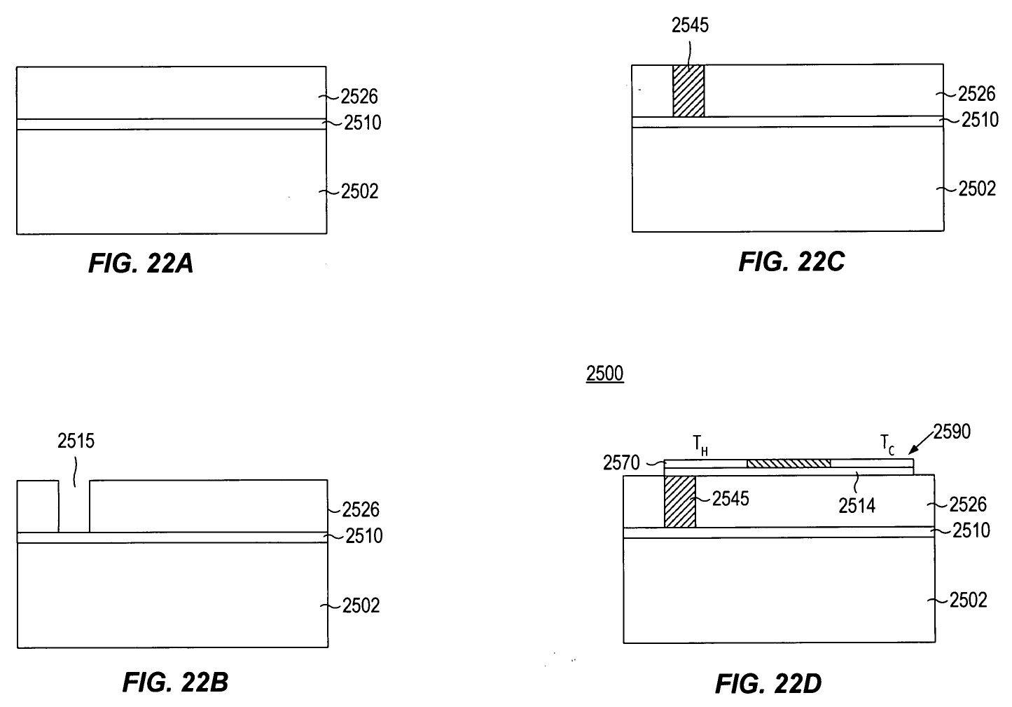

Another embodiment of a vertical heat rejection structure 2500 is depicted in FIGS. 22A-22D. In this embodiment a silicon wafer 2502 is coated with a layer of platinum 2510. An insulating layer 2526 of parylene N, preferably 10-50 μm thick, is deposited on the platinum layer 2510 (FIG. 22A) and patterned to create thermal via openings 2515, as shown in FIG. 22B. Then a metal, e.g. copper, nickel, or gold, is plated onto the structure, filling the thermal via openings to create thermal plugs 2545, as shown in FIG. 22C. A thermally conductive electrically insulating layer 2514, such as a thin oxide, nitride, or other dielectric, may be deposited, then a thermoelectric cooler 2590 may be formed on this structure by any of the techniques described herein. The hot side 2570 of the thermoelectric cooler 2590 is in thermal contact with the thermal plug 2545 by way of the (preferably thin) dielectric layer 2514. While FIG. 22 depicts the hot side 2570 positioned directly above the thermal plug 2545, it will be apparent with reference to FIGS. 21A and 21B that the thermoelectric cooler 2590 could be positioned to the side of the thermal plug 2545 and a thermal pad (not shown) employed to provide thermal coupling between the plug 2545 and the hot side 2570 of the thermoelectric cooler 2590.

Insulating layer 2526 may include a single layer of parylene N or parylene F, a layer of aerogel coated with parylene N, or a multiple layer arrangement of insulating layers. An upper layer of parylene is advantageous for subsequent fabrication of the thermoelectric device 2590. In some embodiments, the thermoelectric device 2590 is preferably formed directly on the surface of the insulating layer 2526 (e.g., particularly if the surface of layer 2526 is a parylene layer surface), and the electrically insulating layer 2514 only utilized between hot fingers 2570 and the thermal plug 2545.

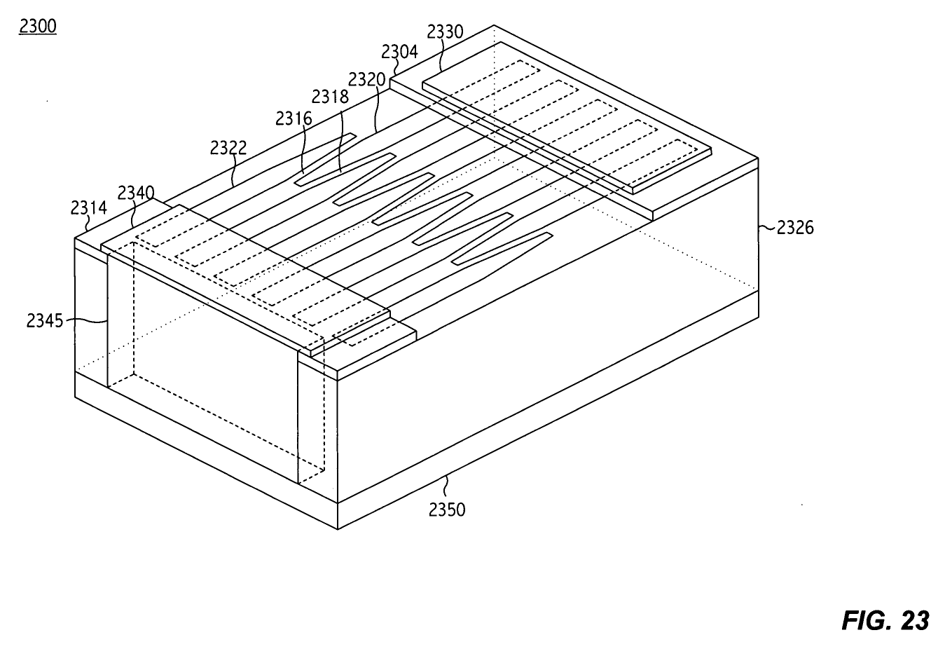

FIG. 23 schematically depicts a three-dimensional view of the top portion of a vertical heat rejection structure 2300 as described above with reference to FIG. 21A. A lateral thermoelectric device 2390 has interdigitated tapered hot 2322 and cold 2320 electrodes separating alternating thermoelectric devices 2316, 2318 of complementary conductivity type. An electrically insulating thermal conductor 2304 is interposed between the cold electrodes 2320 and a thermally conducting cold pad 2330. A second electrically insulating thermal conductor 2314 is interposed between the hot electrodes 2322 and a thermally conducting hot pad 2340. During operation in cooling mode, a source of heat (not shown) such as a laser diode device, an integrated circuit, a photodiode device, etc., may be thermally coupled to the cold pad 2330, such as by direct attachment thereto using, for example, epoxy, solder, or other suitable attachment technique. The hot pad 2340 is thermally connected by a thermally conducting plug 2345 to the support base 2350 where heat can be removed from the system by way of a heat sink, radiator, or other heat transfer system (not shown).

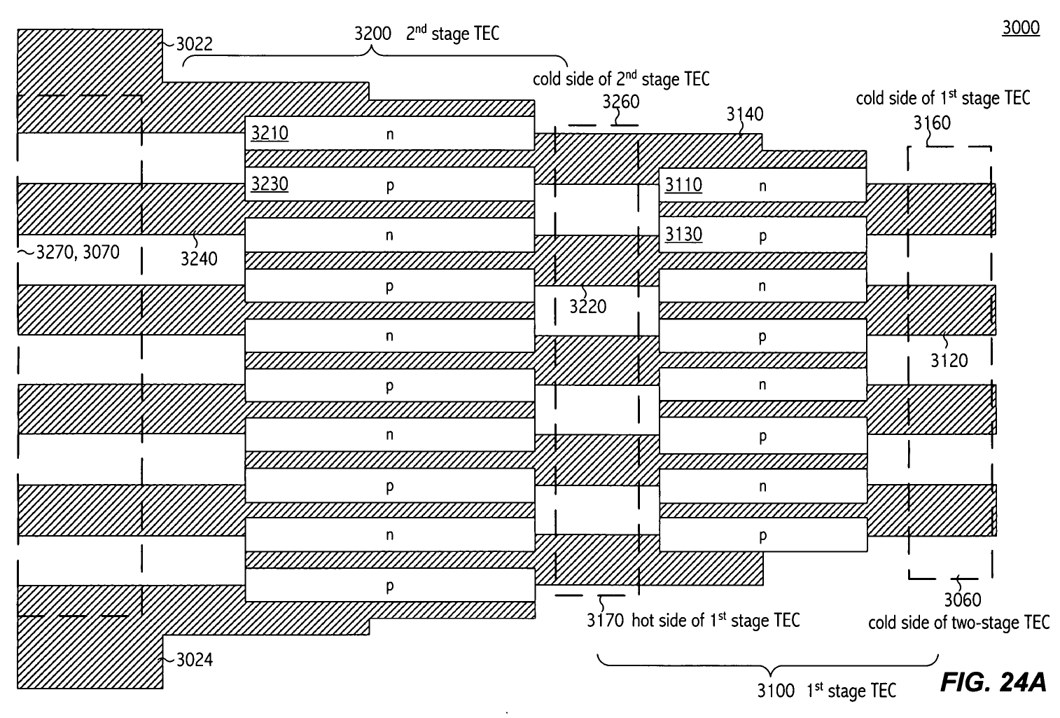

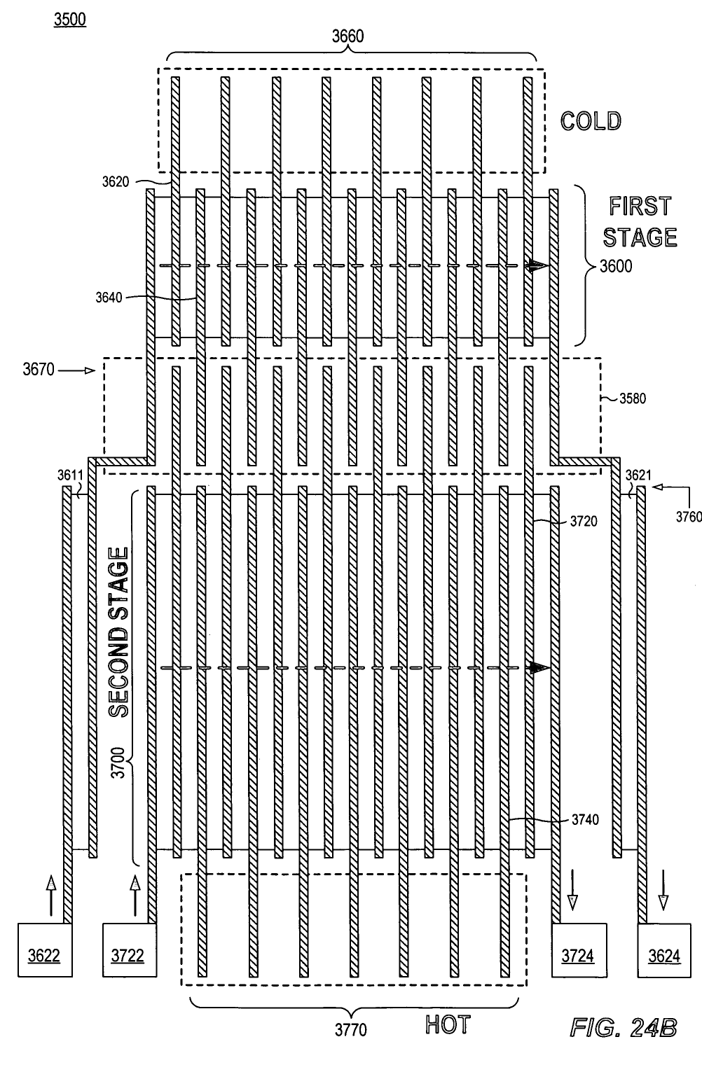

FIG. 24A shows a plan view of a two-stage thermoelectric cooler 3000. A first stage thermoelectric cooler 3100 comprises alternating complementary thermoelectric elements 3110, 3130 connected in series. Thermoelectric devices 3110, 3130 are separated by interdigitated electrodes 3140, 3120 coupled respectively to the hot side 3170 and cold side 3160 of the first stage. During operation, the first stage thermoelectric cooler 3100 produces a temperature differential between its hot 3170 and cold 3160 ends determined by the properties of the thermoelectric device 3100 including its dimensions. A second stage thermoelectric cooler 3200 is connected to the hot side 3170 of the first stage 3100 by its own cold electrodes 3220. During operation, the second stage thermoelectric cooler 3200 produces a temperature differential between its hot side 3270 and cold side 3260 determined by the properties of the thermoelectric device 3200 including its dimensions. The outermost hot electrodes 3022, 3024 (i.e., the first and last numbered electrodes of this group of “hot side” electrodes) of the second stage thermoelectric cooler 3200 are connected to an external voltage source. Current flowing between these electrodes 3022, 3024 splits to flow through both first 3100 and second 3200 stage thermoelectric coolers. The temperature differential produced by the two-stage thermoelectric cooler 3000 between its cold side 3060, i.e. the cold side 3160 of the first stage thermoelectric cooler 3100, and its hot side 3070, i.e. the hot side 3270 of the second stage thermoelectric cooler 3200, equals the sum of the two temperature differentials developed across the individual stages. While FIG. 24A depicts a two-stage thermoelectric cooler, it should be understood that multiple additional stages could be formed by connecting additional thermoelectric cooler stages in thermal series. The use of multiple stages may allow more efficient operation of the apparatus for a given temperature differential, in addition to the achievement of greater temperature differentials than feasible with a single stage.

FIG. 24B depicts a plan view of a two-stage thermoelectric cooler 3500. A first stage thermoelectric cooler 3600 comprises alternating complementary thermoelectric elements connected in series and separated by interdigitated electrodes 3640, 3620 coupled to the hot side 3670 and cold side 3660, respectively of the first stage 3600. During operation, current flows from electrode 3622 through the first stage thermoelectric cooler 3600 to electrode 3624. This produces a temperature differential between the hot side 3670 and cold side 3660 determined by the properties of the thermoelectric device 3600 including its dimensions. Electrodes 3622 and 3644 may be thermally isolated from the outermost hot electrodes 3640 by thermoelectric elements 3611 and 3621, respectively. Hot electrodes 3640 are thermally coupled to an intermediate thermal pad 3580. A second stage thermoelectric cooler 3700 is also thermally coupled to the thermal pad 3580 by its own cold electrodes 3720. During operation, the second stage thermoelectric cooler 3700 produces a temperature differential between its hot side 3770 and cold side 3760 determined by the properties of the thermoelectric device 3700. The outermost hot electrodes 3722, 3724 (i.e., the first and last numbered electrodes of this group of “hot side” electrodes) of the second stage thermoelectric cooler 3700 are connected to an external voltage source. The temperature differential produced by the two-stage thermoelectric cooler 3500 between its cold side (the cold side 3660 of the first stage thermoelectric cooler 3600) and its hot side (the hot side 3770 of the second stage thermoelectric cooler 3700) equals the sum of the two temperature differentials developed across the individual stages. The respective voltage expressed across the first and second stage are each independently controllable, and may result in greater efficiency of operation.

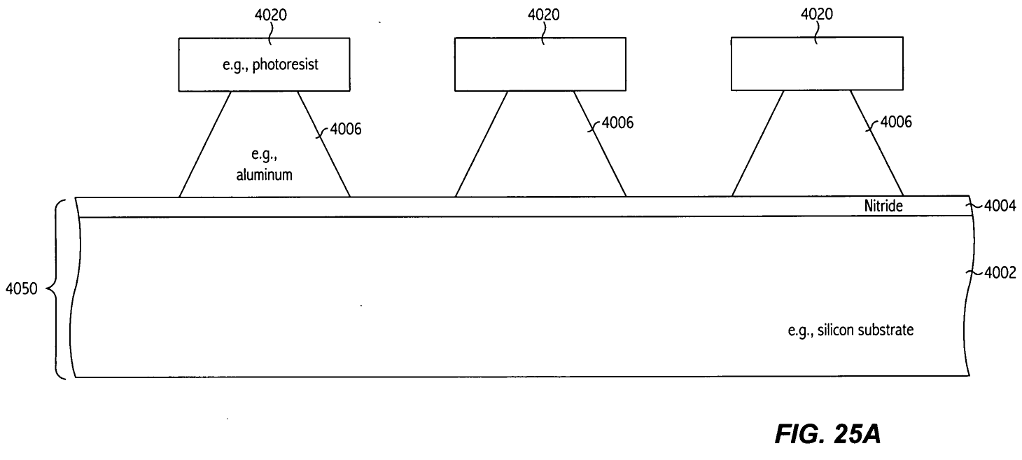

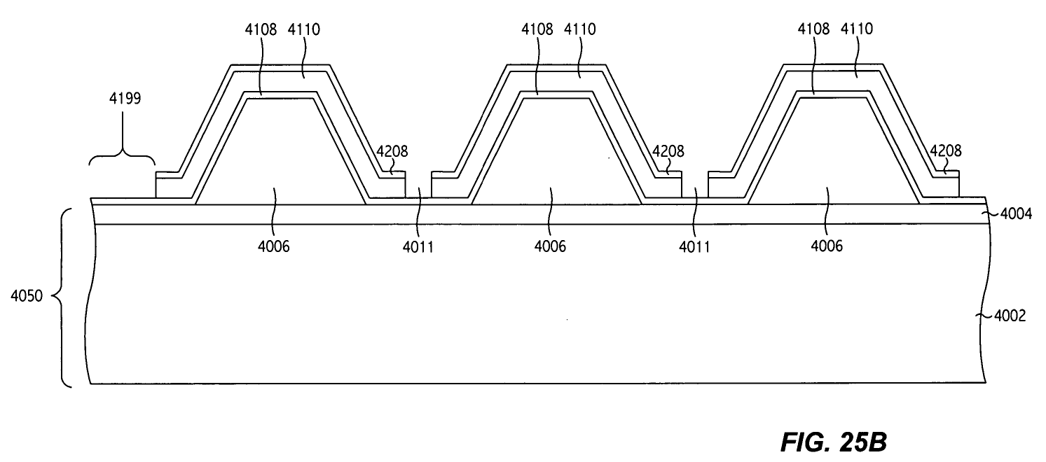

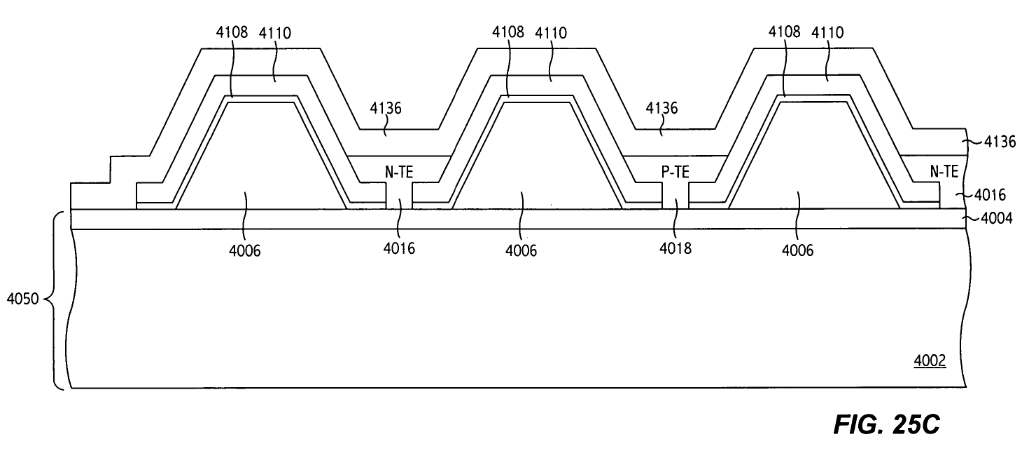

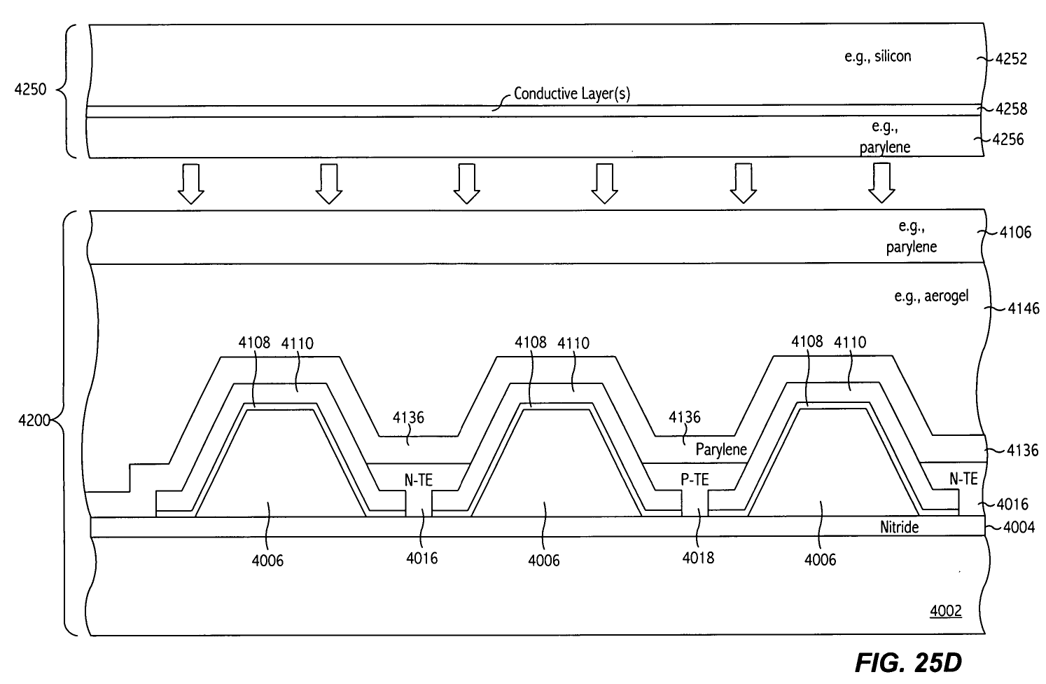

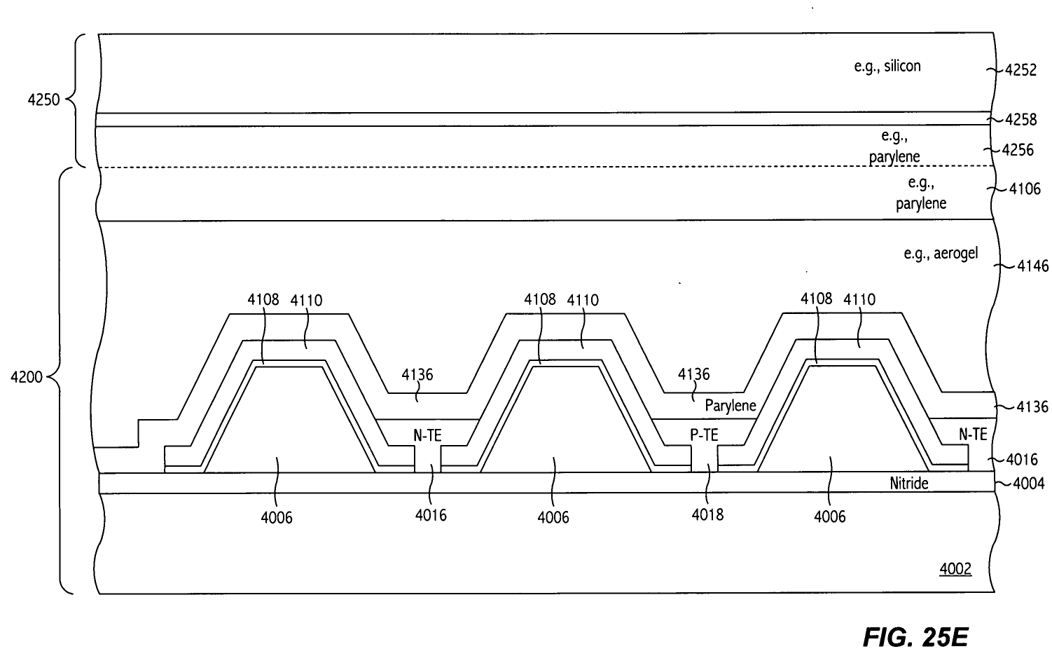

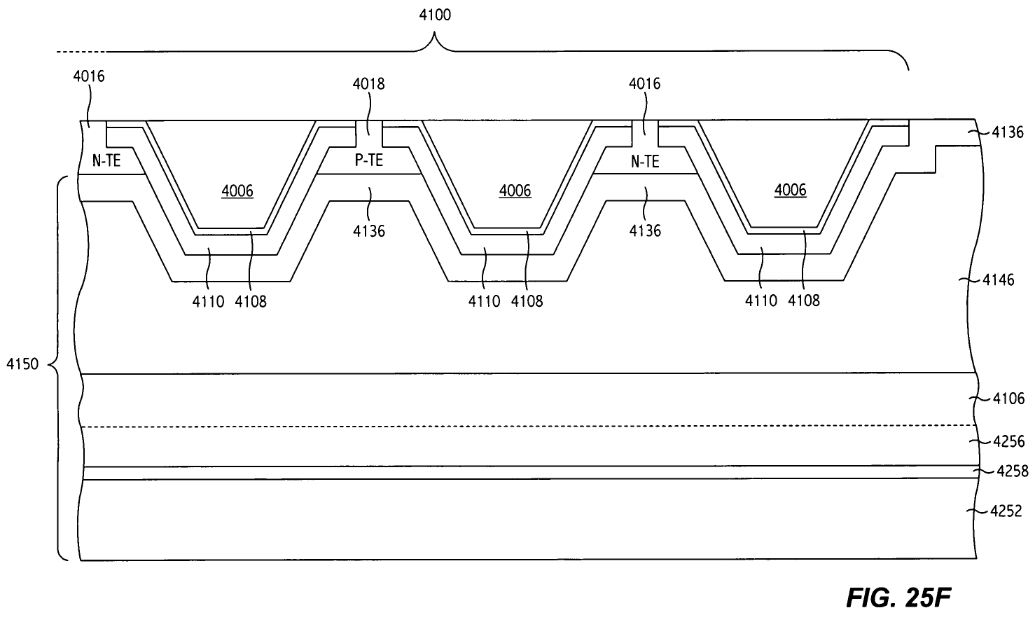

Another exemplary method of forming lateral thermoelectric devices is illustrated in FIGS. 25A-25F. Referring first to FIG. 25A, a supporting structure 4050 is made, for example, from a substrate 4002, e.g. a silicon wafer, coated with a dielectric layer 4004, here a layer of low-stress silicon nitride (Si₃N₄). A blanket layer of high-conductivity metal such as Al or Cu is deposited (e.g., sputtered) to a thickness of 1-2 μm and is patterned by selectively protecting areas with photoresist 4020 and etching with an intentional undercut profile to produce conducting ribs 4006.

Referring now to FIG. 25B, an adhesion layer 4108 is deposited over the conducting ribs 4006 and a low contact resistance layer 4110 of about 150-200 nm of Pt is deposited atop the adhesion layer 4108, or directly onto the conducting ribs 4006 when no adhesion layer is necessary. The Pt layer 4110 is topped by a thin layer 4208 of TiW or other suitable material which will act as a hard mask for patterning the metal layers. The top layer of TiW 4208 is patterned photolithographically and plasma etched using a fluoride such as CF₄ or SF₆ to define gaps 4011. After stripping the remaining photoresist the Pt layer 4110 is plasma etched using dry Ar. The remaining exposed TiW, including portions of layer 4108, is removed using a wet etch to define the electrodes of the device. The resulting structure has electrodes that are thicker in the center than along their longitudinal edges (i.e., here, such edges being in a direction normal to the plane of the page). In some embodiments, not all regions of the supporting structure 4050 are covered with thermoelectric device structure; region 4199 is such an area outside the active thermoelectric device region.

Thermoelectric elements 4016 and 4018 of FIG. 25C are formed using processes described elsewhere herein, including those with reference to FIG. 7 or 8. The whole wafer is then protected with a thin layer of parylene 4136. While FIG. 25C shows the parylene layer 4136 making direct contact with the thermoelectric material, in some embodiments other layers (e.g., oxide layers) previously deposited on the thermoelectric material may remain between the parylene layer 4136 and the thermoelectric material.

As shown in FIG. 25D, a thermally insulating layer 4146 is deposited on the parylene-protected structure of FIG. 25C and topped with a bonding layer 4106 to form a completed thermoelectric wafer structure 4200. The thermal insulation layer 4146 may be a layer of aerogel a few microns thick. Silica, alumina, or titania aerogels may be formed by common processes such as spinning on a precursor solution, catalyzing the sol-gel reaction, and driving out remaining volatiles and water by supercritical drying at about 100° C. in a carbon dioxide atmosphere. This aerogel application process may be repeated until the thermal insulation layer 4146 is of the desired thickness, about 5 μm in some cases. The bonding layer 4106 may be a layer of parylene. Note that FIG. 25D is not drawn to relative scale. For example, a parylene layer 4106 may be up to about 75 μm thick.

While fully operable at this point, the thermoelectric wafer structure 4200 may be bonded to a carrier structure 4250, as described previously with reference to FIGS. 19 and 20. One example of such a carrier structure would be a substrate 4252, e.g. a silicon wafer, onto which a conductive layer or layers 4258 and a bonding layer 4256, e.g. of parylene, have been deposited. Referring to FIG. 25E, the bonding layer 4256 of the carrier structure 4250 contacts the bonding layer 4106 of the thermoelectric wafer structure 4200. When both bonding layers are parylene, they are fused together to form a strong bond using moderate heat and compression. Typical conditions for fusing parylene bonding layers are 1.5 MPa compressive stress and a temperature above 100° C. for two hours, with a chuck holding temperature of about 150° C.

The thermoelectric device structure of FIG. 25F is ready for separation into individual die. The original substrate 4002 and dielectric layer 4004 have been removed, either entirely or at least in the regions of the thermoelectric device layers 4100. The thermoelectric device layers 4100 are supported by supporting structure 4150, formed from carrier structure 4250 and the protective layer 4136, thermally insulating layer 4146, and bonding layer 4106 previously deposited on the thermoelectric device layers 4100.

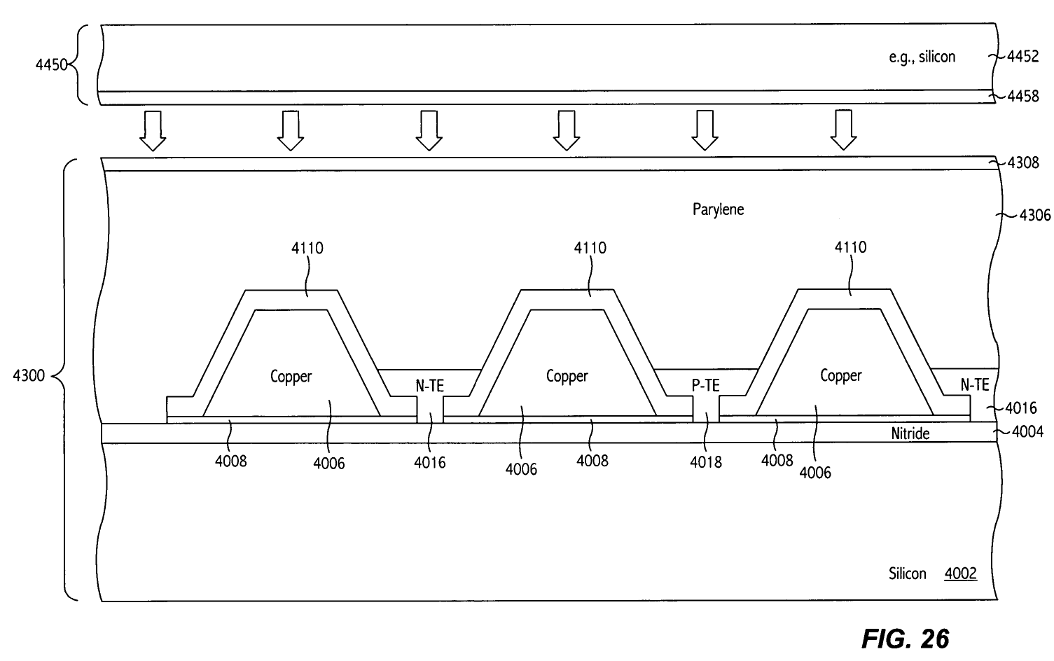

FIG. 26 depicts another exemplary thermoelectric wafer structure 4300 and carrier structure 4450. If material chosen for the core of the conducting ribs 4006 is Cu, an adhesion layer 4008 of 10-50 nm of TiW is deposited on the nitride-coated substrate 4002 before the Cu is deposited. No adhesion layer is necessary for Pt deposited on Cu, so layer 4110 directly contacts the ribs 4006. The hard mask layer (4208 in FIG. 25B) may still be employed, if desired. In this embodiment the protective layer 4306 of parylene has been deposited to a thickness sufficient to provide adequate thermal insulation without a layer of aerogel. A conductive layer 4308, for example, of gold, is deposited on the surface of the parylene. The carrier substrate 4452, e.g. a silicon wafer, is also topped with a conductive layer 4458, preferably terminating with a layer of soft metal. The conducting layers 4458 and 4308 are brought together and thermo-compression bonded, after which the original substrate and dielectric layers can be removed to provide access to the thermoelectric devices. In such a structure, the parylene layer 4306 may be viewed as a first supporting layer, and the silicon wafer 4452, conductive layer 4458, and conductive layer 4308 together may be viewed as a second supporting layer or supporting base.

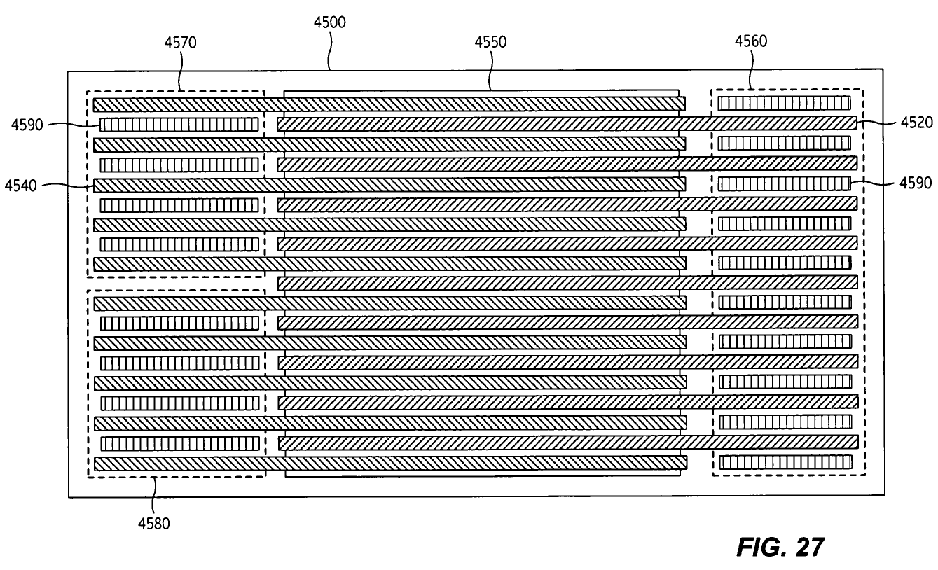

FIG. 27 shows a top view of an exemplary thermoelectric device structure. A thermoelectric device 4500 contains a thermoelectric active region 4550 and thermal pads 4560, 4570, and 4580. Cold electrodes 4520 extend from the thermoelectric active region 4550 to the cold pad 4560. Hot electrodes 4540 extend from the thermoelectric active region 4550 to one of the two hot pads 4570 or 4580. Each hot pad is electrically connected to the power supply for the thermoelectric device and a potential is developed across the two pads during operation of the device. The two outermost hot electrodes 4540 make electrical, as well as thermal, contact with the hot pad 4570 or 4580 on which it sits. The remaining hot electrodes 4540 are thermally coupled, but preferably not electrically coupled, to one of the hot pads 4570 or 4580. Thermal shunt ribs 4590 are located between cold electrodes 4520 on the cold pad 4560 and between hot electrodes 4540 on the hot pads 4570 and 4580 and help maintain a more constant temperature profile across the hot and cold pads.

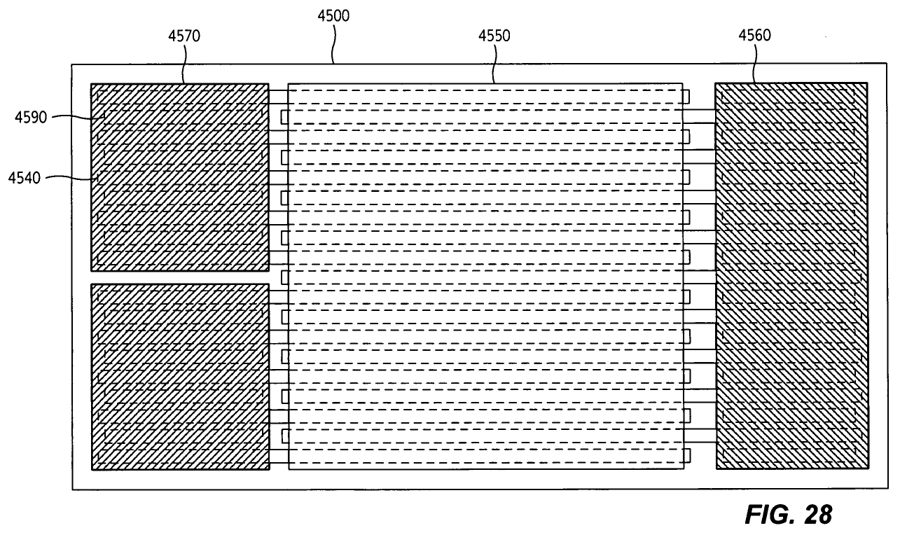

FIG. 28 shows another view of the thermoelectric device structure of FIG. 27, emphasizing the hot pads 4570 and 4580 and the cold pad 4560. Such pads may be disposed above the electrodes (as regards a finished structure) to provide an attachment area for a device (e.g., to the cold pad) and for electrical and thermal coupling to the hot pads 4570 and 4580 (and thus to the first and last hot electrodes). In some embodiments, these hot pads may be coupled to a pair of plugs 2545 as shown in FIG. 22A-22D. In some embodiments, the hot pads may be disposed below the electrodes, and may make direct contact to one or more plugs 2545 or other suitable thermal conduction structure to transfer heat from the hot side of the lateral thermoelectric device to the back side of the vertical structure.

FIG. 29 shows a cross-sectional view of an exemplary thermal pad structure. An adhesion layer 4508, e.g. 10 nm of TiW, is deposited on a substrate 4502 coated with a dielectric layer 4504, for example, 300 nm of low-stress silicon nitride. A blanket layer 4510 of highly conductive material, e.g. 400 nm of gold, is then deposited on the adhesion layer 4508 and then etched to form the thermal pad. The thermal pads are large structures, typically hundreds of microns in extent, for example, 500 μm by 200 μm. An electrically insulating material 4520 is then deposited and patterned. This insulating material may be a few tens of nanometers (e.g., 50 nm) thick PECVD silicon dioxide, CVD silicon nitride or sputtered alumina or aluminum nitride. Another adhesion layer 4528 is deposited, and conducting ribs are formed as described elsewhere herein, including with reference to FIGS. 25A and 25B. While all dimensions are merely exemplary, the ribs 4590 and 4520 that are depicted in FIG. 29 are spaced on 16 μm centers, with peaks approximately 10 μm wide, and about 13 μm wide at the base. Electrode material extends approximately 1 μm from each longitudinal edge of the rib, leaving a gap about 1 μm wide. Ribs 4590 in electrical contact with the conductive layer 4510 act as thermal shunts ribs. Ribs 4520 are electrically isolated from the conductive layer 4510 and extend into the thermoelectric active region to act as cold (or hot) electrodes of the thermoelectric device.

As mentioned previously, the thermoelectric device structures can be used as grown and patterned on the original fabrication substrates without bonding to carrier substrates. In such embodiments, it may be advantageous to reverse the sequence of fabricating the thermal pads (4560, 4570, and 4580) and ribs (4590, 4520, and 4540). For example, it may be advantageous to recess part or all of the ribs 4590, 4520, and 4540 in pits or trenches formed in the original fabrication substrate, form the thermoelectric elements of the thermoelectrically active region 4550, and then form the thermal pads 4560, 4570, and 4580.

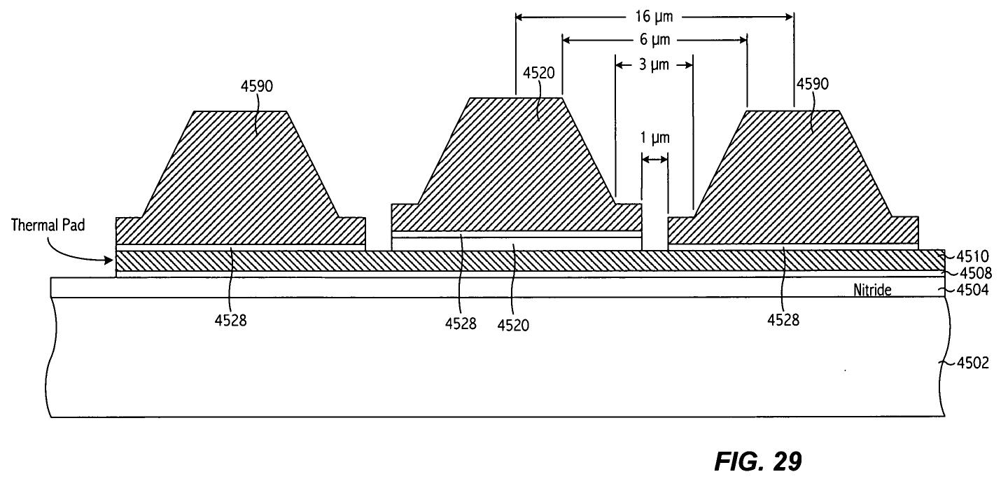

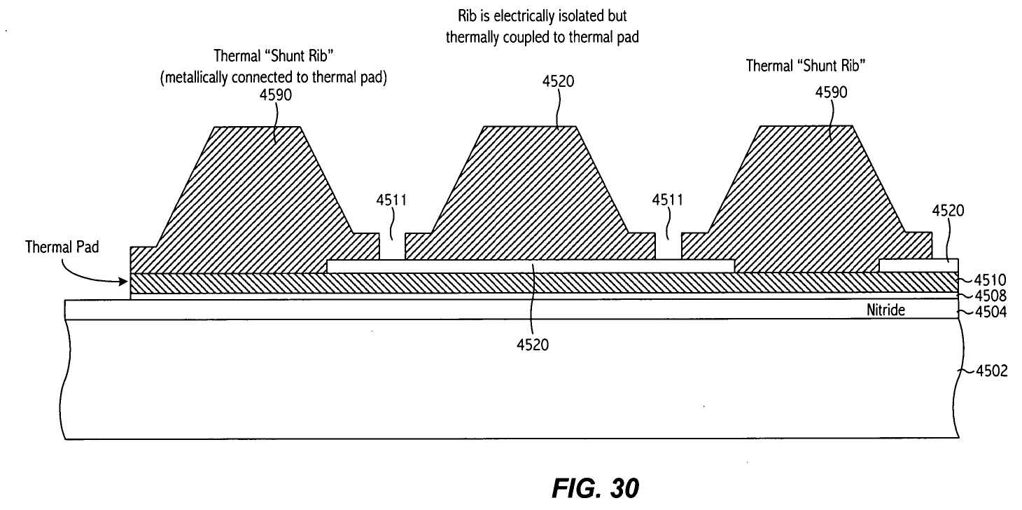

FIG. 30 shows another possible thermal pad structure. When the properties of the materials chosen for the ribs 4590, 4520 and the conductive layer 4510 permit, adhesion layer 4528 may be omitted. Furthermore, the electrically insulating material 4520 may extend through the region between ribs 4590, 4520, even partially underlying thermal shunt ribs 4590. This practice obviates the need for precise alignment when defining gaps 4511. The electrically insulating material 4520 may be removed along with the metal layers when gaps 4511 are defined, or it may remain. Alternatively, the dielectric layer 4520 may also be disposed beneath the thermal shunt ribs 4590, which still maintain some degree of thermal conduction from one side of a thermal pad to the other.

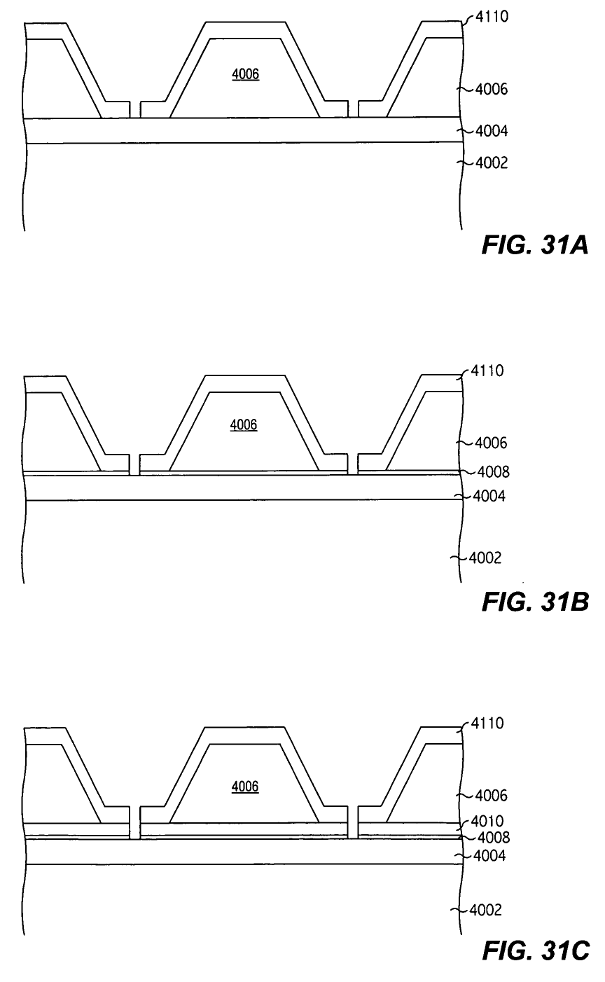

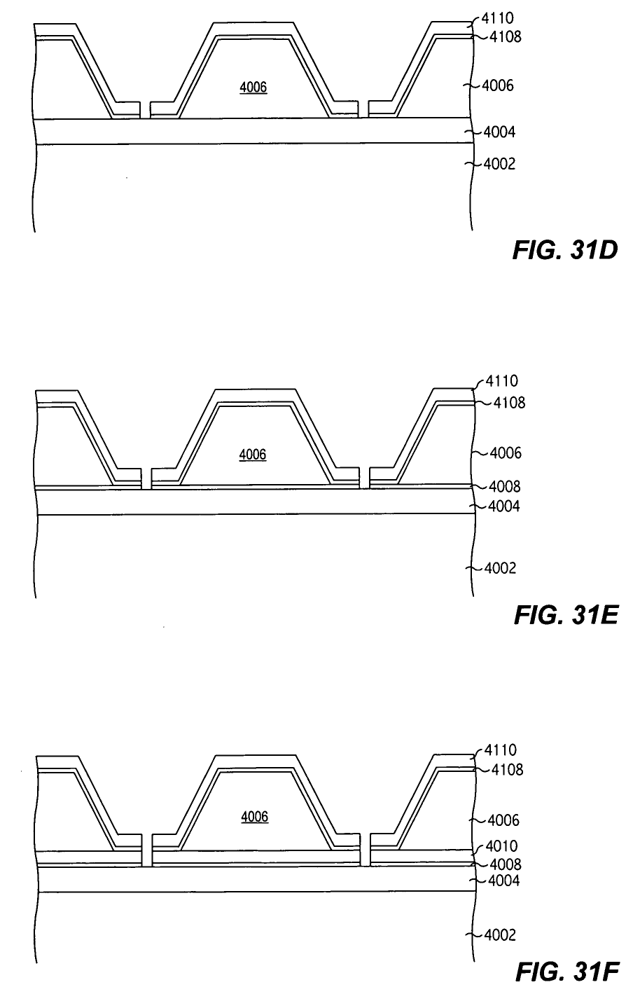

FIGS. 31A-31F depict other exemplary rib structures that may be used in the embodiments described herein. In FIG. 31A a rib is formed by depositing conducting layer 4006, e.g. aluminum, directly on the nitride layer 4004 formed on the substrate 4002. A layer of low contact resistance conductor 4110 is deposited directly on the rib core material 4006. The rib of FIG. 31B interposes an adhesion layer 4008, e.g. Ti or TiW, between the nitride 4004 and the rib core material 4006. As shown in FIG. 31C, an additional conducting layer 4010, e.g. Pt, may be deposited beneath the rib core layer 4006 if desired. FIG. 31D shows the rib structure of FIG. 31A with the addition of an adhesion layer 4108, e.g. TiW, as was shown in FIGS. 25B-25F. FIG. 3 IE depicts the structure of FIG. 31B with adhesion layer 4108 interposed between the rib core layer 4006 and the low contact resistance layer 4110. Finally, FIG. 3 IF shows the rib structure of FIG. 3 IC in which an adhesion layer 4108 is deposited atop the rib core layer 4006 and the low contact resistance layer 4110 is deposited atop the adhesion layer.

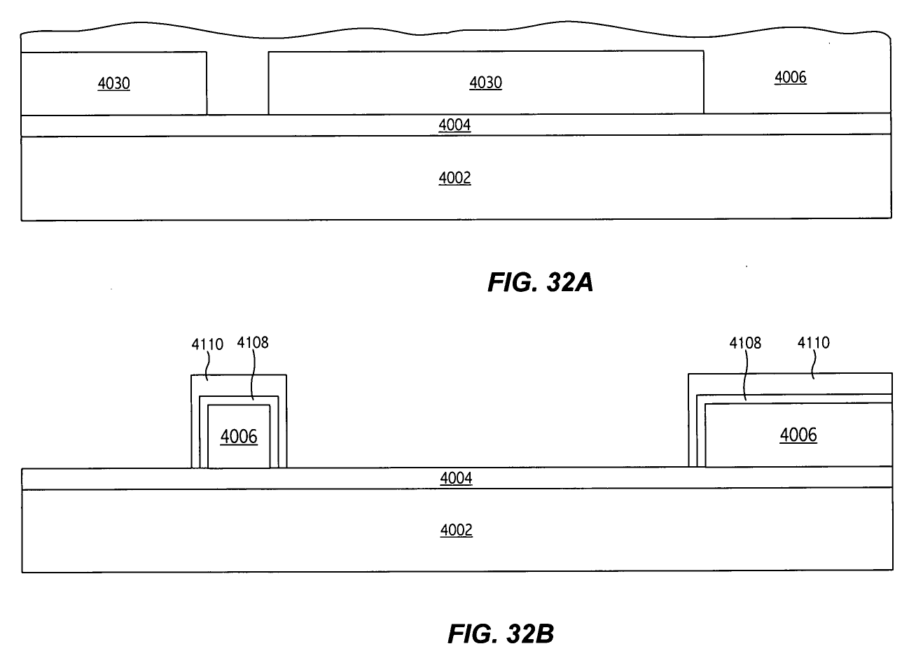

FIGS. 32A and 32B show another exemplary method of forming a conductive rib structure. As shown in FIG. 32A, a relatively thick layer of oxide 4030 is deposited on a substrate 4002 covered with a nitride layer 4004. The oxide 4030 is patterned and a layer of metal 4006 is deposited. The structure is then leveled, for example by chemical/mechanical polishing, and the oxide layer 4030 removed. An adhesion layer 4108 and a low contact resistance layer 4110 can then be deposited as described above resulting in the structure of FIG. 32B.

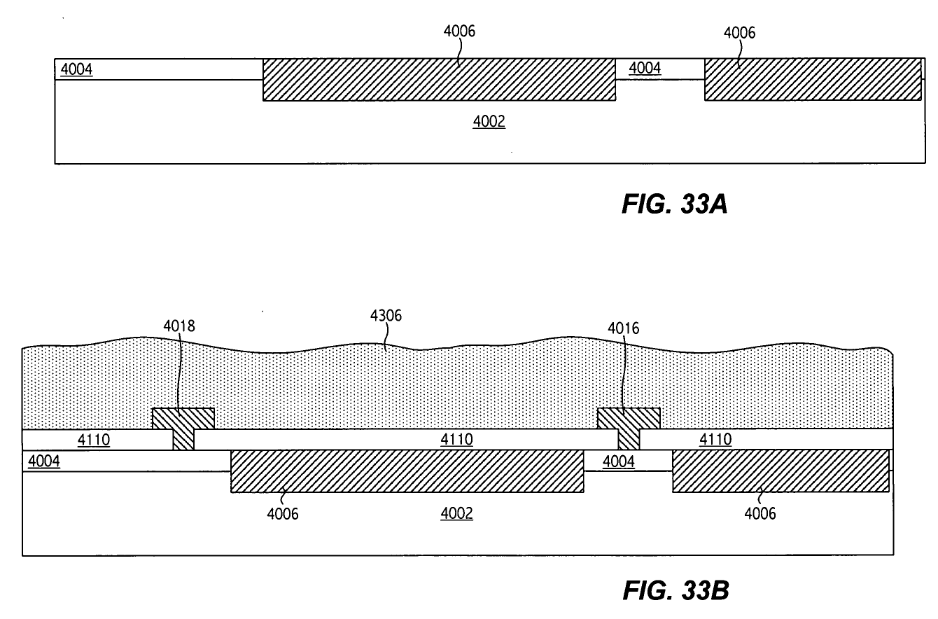

FIGS. 33A and 33B show another exemplary method of forming a conductive rib structure. As shown in FIG. 33A, pits or trenches are formed in a substrate 4002 covered with a nitride layer 4004. Metal 4006 is deposited in the pits and the structure is then leveled, for example by chemical/mechanical polishing. A low contact resistance layer 4110 can then be deposited and patterned and thermoelectric elements 4016 and 4018 formed as described above. The entire structure can then be coated with a thick protective layer 4306, e.g. of parylene, resulting in the structure of FIG. 33B. This structure may be combined with other techniques described herein to implement useful thermoelectric devices.

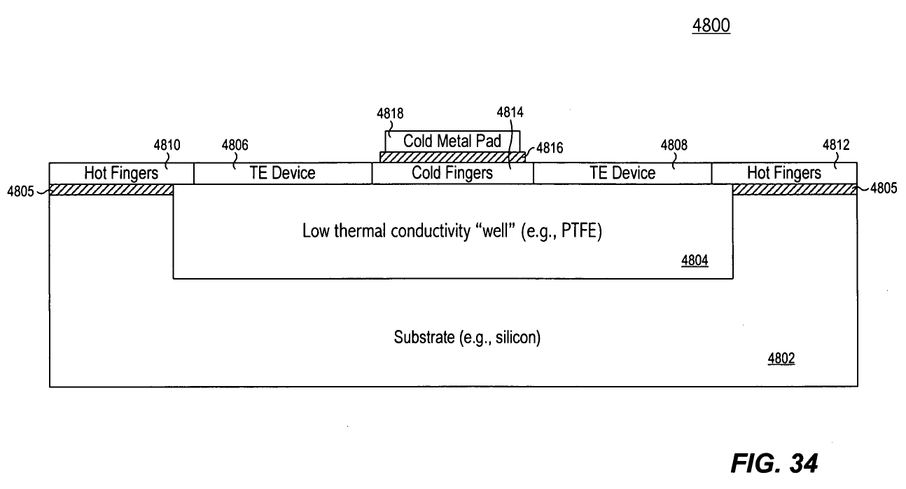

FIG. 34 shows an example of a lateral thermoelectric device structure 4800 formed upon a structured substrate 4802 which includes a “well” 4804 or recessed region of low conductivity material such as, for example, polytetrafluoroethylene (PTFE). Hot fingers 4810, 4812 are insulated from the substrate 4802 by a layer of dielectric 4805. The hot fingers 4810, 4812 make thermal contact with the hot sides of the lateral thermoelectric device(s) 4806, 4808, respectively which overlie the low thermal conductivity well 4804. Cold fingers 4814 make contact with the cold sides of the lateral thermoelectric device(s) 4806, 4808, and are thermally insulated from the substrate 4802 by the layer of low thermal conductivity material forming the well 4804. As described elsewhere herein, a layer of electrically isolating and thermally conductive material 4816 provides thermal contact and electrical isolation between the cold fingers 4814 and a cold pad 4818, to which a workpiece to be cooled (not shown) may make thermal contact.

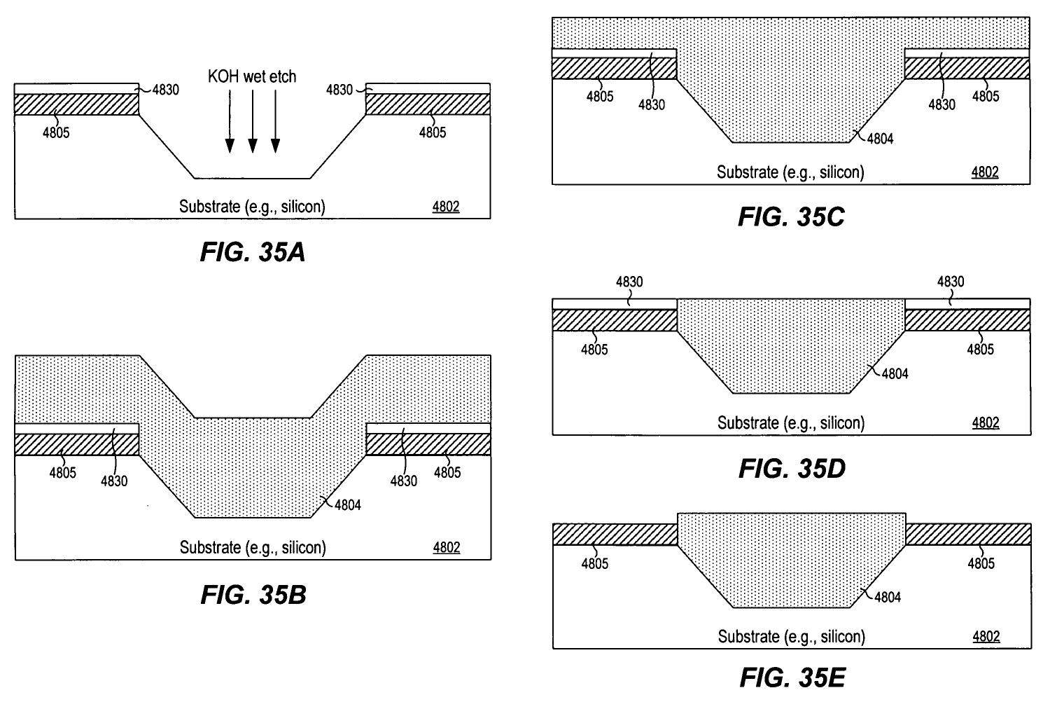

FIGS. 35A-35E illustrate one method of fabricating the low thermal conductivity well 4804. As seen in FIG. 35A, a layer of dielectric 4805, such as layer of LPCVD SiN up to about 300 nm thick, is formed on a substrate 4802 such as silicon, as described in more detail elsewhere herein. A layer of metal 4830, e.g. a bilayer of Cr/TiW about 50 nm thick, is deposited on the dielectric 4805. Both of these layers are then patterned to expose the substrate 4802 in regions where the well 4804 is desired. The substrate 4802 then undergoes an etching process which removes substrate material in the unprotected region. In an exemplary process, KOH may be used to wet etch a silicon substrate 4802 to a depth of about 50 μm, leaving characteristically sloped sides, as shown. Referring to FIG. 35B, a layer of low thermal conductivity material 4804 is then deposited to fill the etched pit. In an exemplary embodiment, Teflon® AF 1600, Teflon® AF 2400, or a mixture of the two is deposited to a thickness of about 60 μm by spin coating or dip coating. After reflowing the fluoropolymer at a temperature above about 300° C., the structure of FIG. 35C may result. When the polymer has stopped flowing, the excess may be removed by CMP until the surface of metal layer 4830 is exposed as in FIG. 35D. This metal layer can then be removed by wet or dry etching, such that the structure of FIG. 35E may result. FIG. 35E exaggerates the “bump” of fluoropolymer that may remain after removal of metal layer 4830; for such a step may be only 50 nm in height. Note also that the layers of dielectric 4805 and low thermal conductivity material 4804 may be viewed as layers, even after patterning and selective removal such that they no longer blanket the entire substrate.

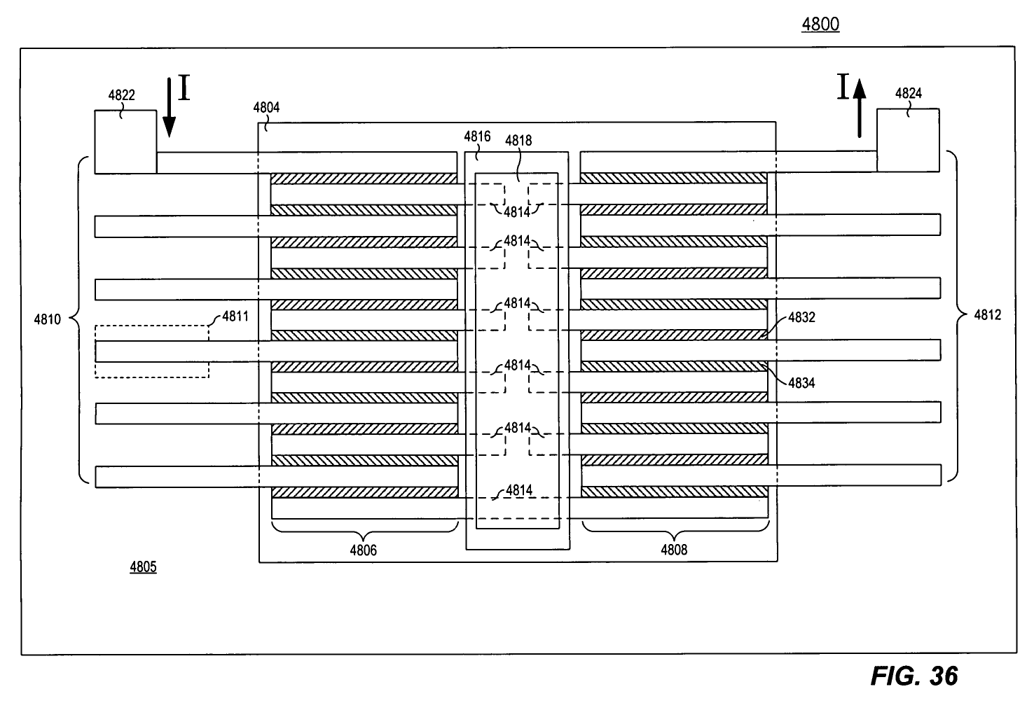

FIG. 36 shows a plan view of the exemplary lateral thermoelectric device structure 4800 of FIG. 34. Hot fingers 4810, 4812 and the electrodes 4822 and 4824 are electrically insulated from the substrate by a layer of dielectric 4805. A low thermal conductivity well 4804 has been formed in part of the substrate. As described in more detail elsewhere herein, hot electrodes 4810, 4812 and cold electrodes 4814 are formed on the structured substrate and alternating n-type thermoelectric elements 4832 and p-type thermoelectric elements 4834 couple them in electrical series, forming lateral thermoelectric devices 4806 and 4808. In the depicted embodiment, lateral thermoelectric devices 4806 and 4808 share a common cold electrode to form a single current path. In an alternative embodiment, electrical contact could be made to the bottom-most left-hand hot electrode, essentially cutting the structure in half, as illustrated in FIGS. 11-14, for example. During operation, current flows from electrode 4822 through lateral thermoelectric devices 4806 and 4808 to electrode 4824, while a thermal differential develops between the hot fingers 4810, 4812 and the cold fingers 4814. Dielectric layer 4816 overlies a portion of cold fingers 4814 that extend beyond the active device regions 4806 and 4808, insulating the fingers electrically from cold pad 4818 while allowing thermal contact between the cold fingers 4814 and the cold pad 4818. For simplicity, both hot fingers 4810, 4812 and cold fingers 4814 are shown as having simple rectangular outlines, but as described elsewhere herein some portion of the fingers may be made larger in size (indicated in FIG. 36 by dashed feature 4811) to increase thermal transfer to the substrate 4802 (disposed below the dielectric layer 4805).

In the various embodiments shown herein, the effective transport length of the lateral thermoelectric elements, in the direction of current flow, may be less than the electron-phonon thermalization length A. Values of the electron-phonon thermalization length in typical thermoelectric elements is approximately 500 nm (0.5 μm). In the various “thermoelectric elements first” process embodiments described above, such effective thermoelectric element transport length is largely determined by the spacing between the electrodes which overlap the thermoelectric elements, rather than the defined “length” of the thermoelectric element, as etched (i.e., in the direction of current flow), before formation of the electrodes. In the various “electrode first” process embodiments described above, the effective transport length of the thermoelectric elements is largely defined by the size of the gap between adjacent electrodes, particularly if the thermoelectric material forms robust contact with the sidewalls of such electrodes (e.g., using an electrode process, such as that described in relation to FIGS. 9A-9F, having interface layers formed on the sidewalls of the electrodes). In such a process, the overlap of the thermoelectric material on the top surface of the electrode layers generally contributes little current flow, and therefore contributes little to the effective transport length. In other embodiments, a greater portion of the current through the thermoelectric element may flow through such overlap, and the effective transport length is potentially somewhat larger than the physical gap between electrodes. In other embodiments, the effective transport length of the thermoelectric element is larger than the electron-phonon thermalization length.

As used herein, a monolithic structure is a structure formed upon a single substrate, although such a monolithic structure may be transferred to another supporting structure or substrate, and the original substrate upon which such monolithic structure is originally formed during original processing may be later removed. As used herein, a monolithicly formed thermoelectric device is fully operable as monolithically constructed. Other layers, including a supporting “carrier substrate” may be added later using a non-monolithic technique, but the device is still intended to be termed a monolithic thermoelectric device. In preferred embodiments, a protective layer and/or thermally isolating layer may also be formed monolithically.

As used herein, a first layer or structure having a substantially lower thermal conductivity than a second layer or structure may be assumed to be at least a factor of 10 lower, unless the context clearly precludes such interpretation. Moreover, an electrode or other structure having a width that is substantially larger than a space between such electrodes or such other structures may be assumed to be a factor of 4 larger, unless the context clearly requires otherwise.

As used herein, a “layer” need not be continuous across an entire structure. For example, a layer may be formed in a region, such as a “well” region in a substrate. In addition, even a layer that may have been formed across an entire structure may have portions subsequently removed, leaving one or more remaining features of the layer. Moreover, a layer need not be planar across its entire extent, as such a layer may be conformal to irregular structures upon which the layer is disposed. A layer as used herein may include one or more constituent layers, and thus may be viewed as potentially including a compound layer of more than one dissimilar material layers, unless the context clearly precludes such interpretation.

References here to a parylene layer may include parylene N, parylene C, parylene F, a compound layer (i.e., sandwich layers) of one or more layers of each, a compound layer including a parylene layer, an aerogel layer, and another parylene layer, and similar variations including a parylene layer, unless the context clearly precludes such an interpretation.

As used herein, “coupled” may mean coupled directly or indirectly, e.g. via an intervening layer or layers. Likewise, the phrase “disposed upon a supporting structure” need not indicate the absence of intervening layers between the supporting structure and layers or devices disposed thereon. Similarly, a layer “overlying” another structure does not necessarily indicate the absence of intervening layers between the layer and other structure. As used herein, “tapered” need not mean having straight, linear lateral edges. A tapered electrode has a non-uniform width, which may appear triangular, trapezoidal, or stepped when viewed from the top.

A plurality of alternating elements, for example A-B-A or A-B-A-B-A, exists regardless of intervening doubled or extraneous elements. The set of elements A-A-B-A-B-A is a plurality of alternating elements as the phrase is used herein since it contains the sequence A-B-A-B-A, a plurality of alternating elements. Elements that are spaced apart laterally may be essentially coplanar, or may be separated into different layers. Laterally spaced apart elements may be supported by the same material layers, by different material layers, or by no direct means.

While figures depicting electrode configurations have, for clarity, shown a relatively small number of thermoelectric elements, pairs of thermoelectric elements, and electrodes, it will be clear to those skilled in the art that useful thermoelectric devices may be constructed of a single pair of thermoelectric elements coupling two electrodes of one group and one electrode of another group. Furthermore, very large numbers, even hundreds, of pairs of thermoelectric elements may be combined to form useful thermoelectric devices. In multi-stage thermoelectric devices, stages need not be connected in electrical series arrangements. In some embodiments separate stages may be connected in electrical parallel. In some embodiments, two or more stages may be connected in electrical series while other stages may be connected to the series-connected stages in an electrically parallel arrangement.

Various embodiments of the invention have been described. The description of the invention set forth herein is illustrative, and is not intended to limit the scope of the invention as set forth in the following claims. The inventive concepts described herein may be used alone or in various combinations. In addition, although the present invention has been described primarily with reference to a thermoelectric cooling device, the invention may also be used as a power generator for generation of electricity. A thermoelectric device configured in the Peltier mode (as described above) may be used for refrigeration, while a thermoelectric device configured in the Seebeck mode may be used for electrical power generation. Based on the description set forth herein, numerous modifications, changes, variations, substitutions, and equivalents will be apparent to those of ordinary skill in the art without departing from the spirit and scope of the invention, which is defined in the following appended claims.

What is claimed is:

1. A thermoelectric device apparatus comprising:
a plurality of laterally spaced-apart electrodes disposed upon a supporting structure; and
at least one complementary pair of thermoelectric elements, each thermoelectric element coupling an electrode to a laterally adjacent electrode.

2. The thermoelectric device apparatus as recited in claim 1 comprising electrodes that are non-uniform in width between adjacent thermoelectric elements coupled thereto.

3. The thermoelectric device apparatus as recited in claim 1 wherein the supporting structure comprises a layer that is formed in a monolithic process for also forming the electrodes and complementary thermoelectric elements.

4. The thermoelectric device apparatus as recited in claim 3 wherein the supporting structure further comprises a carrier substrate attached after monolithic formation of the electrodes, the complementary thermoelectric elements, and the supporting structure layer.

5. The thermoelectric device apparatus as recited in claim 3 wherein the supporting structure further comprises a monolithic fabrication substrate upon which the supporting structure layer is disposed.

6. The thermoelectric device apparatus as recited in claim 3 wherein the supporting structure layer comprises a material chosen from the group consisting of dielectrics having a thermal conductivity of less than 0.1 W/m-K, polymers based upon paraxylylene and its substituted derivatives, fluoropolymers, and aerogels.

7. The thermoelectric device apparatus as recited in claim 1 wherein:
the plurality of laterally spaced-apart electrodes comprises a first group of at least one electrode and a second group of at least two electrodes, said electrodes of said first and second groups of electrodes being generally coplanar and being disposed within a first region in an alternating, laterally spaced apart manner; and
the at least one complementary pair of thermoelectric elements comprises alternating complementary thermoelectric elements, each element coupling together an electrode of the first group and an adjacent electrode of the second group within the first region.

8. The thermoelectric device apparatus as recited in claim 7 comprising electrodes of at least one of the first and second groups of electrodes which are thicker in a region between opposing longitudinal edges thereof than along said opposing longitudinal edges.

9. The thermoelectric device apparatus as recited in claim 7 comprising electrodes of at least one of the first and second groups of electrodes which are non-uniform in width within the first region.

10. The thermoelectric device apparatus as recited in claim 7 wherein:
the first and second groups of electrodes are disposed upon a particular surface of the supporting structure; and
each thermoelectric element includes at least a portion that is respectively disposed between adjacent coupled-together electrodes.

11. The thermoelectric device apparatus as recited in claim 10 wherein the particular surface of the supporting structure comprises a surface of a material chosen from the group consisting of dielectrics having a thermal conductivity of less than 0.1 W/m-K, polymers based upon paraxylylene and its substituted derivatives, and fluoropolymers.

12. The thermoelectric device apparatus as recited in claim 7 wherein each respective lateral space between adjacent electrodes is non-uniform within the first region.

13. The thermoelectric device apparatus as recited in claim 7 wherein each respective lateral space between adjacent electrodes is less than 1 μm.

14. The thermoelectric device apparatus as recited in claim 7 wherein each respective lateral space between adjacent electrodes is less than an electron-phonon thermalization length of a thermoelectric material comprising the respective thermoelectric element coupling together said adjacent electrodes.

15. The thermoelectric device apparatus as recited in claim 7 comprising electrodes of the first and second group having a width within at least a portion of the first region that is substantially larger than the lateral space between adjacent electrodes within the first region.

16. The thermoelectric device apparatus as recited in claim 7 wherein the complementary thermoelectric elements comprise:
a first group of thermoelectric elements comprising a first homogenous thermoelectric material of a first type; and
a second group of thermoelectric elements comprising a second homogenous thermoelectric material of a second type.

17. The thermoelectric device apparatus as recited in claim 7 further comprising a respective means for making electrical contact to the first and last electrode of the second group of electrodes.

18. The thermoelectric device apparatus as recited in claim 7 wherein the first and second groups of electrodes are radially arranged to form at least a portion of a circle.

19. The thermoelectric device apparatus as recited in claim 7 wherein the thermoelectric device has a thermoelectric element figure of merit (ZT) greater than approximately 1.

20. The thermoelectric device apparatus as recited in claim 7 further comprising:
a third group of at least one electrode and a fourth group of at least two electrodes, said electrodes of said third and fourth groups of electrodes being generally coplanar and disposed upon the supporting structure, and being disposed within a second region in an alternating, laterally spaced apart manner; and
a second group of at least one complementary pair of thermoelectric elements, said second group comprising alternating complementary thermoelectric elements, each element coupling together an electrode of the third group and an adjacent electrode of the fourth group within the second region;
wherein the electrodes of the first and fourth groups are thermally coupled together.

21. The thermoelectric device apparatus as recited in claim 20 wherein a respective electrode of the first group is electrically coupled to a respective electrode of the fourth group.

22. The thermoelectric device apparatus as recited in claim 20 wherein the electrodes of the first group are thermally coupled to the electrodes of the fourth group by way of an intermediate thermal pad outside the first and second regions which overlaps the electrodes of both the first and fourth groups.

23. The thermoelectric device apparatus as recited in claim 7 wherein the supporting structure comprises:
a group of at least one supporting layer disposed on a supporting base, the supporting layer group having a substantially lower thermal conductivity than the supporting base.

24. The thermoelectric device apparatus as recited in claim 23 wherein the supporting layer group is at least 5 μm thick.

25. The thermoelectric device apparatus as recited in claim 23 wherein the supporting layer group has a thermal conductivity of less than 0.1 W/m-K.

26. The thermoelectric device apparatus as recited in claim 23 wherein the supporting layer group comprises a material chosen from the group consisting of dielectrics having a thermal conductivity of less than 0.1 W/m-K, polymers based upon paraxylylene and its substituted derivatives, fluoropolymers, and aerogels.

27. The thermoelectric device apparatus as recited in claim 23 wherein the supporting base comprises a material chosen from the group consisting of a semiconductor and a metal.

28. The thermoelectric device apparatus as recited in claim 23 further comprising:
thermal conduction means for providing thermal conduction between the electrodes of the second group and the supporting base that is substantially greater than any thermal conduction between the electrodes of the first group and the supporting base.

29. The thermoelectric device apparatus as recited in claim 28 wherein:
said first and second groups of electrodes are interdigitated electrodes, said first group of electrodes extending beyond one side of the first region farther than said second group of electrodes, and said second group of electrodes extending beyond a side opposite the one side of the first region farther than said first group of electrodes.

30. The thermoelectric device apparatus as recited in claim 29 wherein:
said thermal conduction means is thermally coupled to electrodes of the second group outside the first region.

31. The thermoelectric device apparatus as recited in claim 30 further comprising:
a first pad disposed outside the first region, said first pad thermally coupled to one or more electrodes of the first group and electrically isolated from all but at most one electrode of the first group.

32. The thermoelectric device apparatus as recited in claim 30 wherein said thermal conduction means comprises a dielectric layer between electrodes of the second group and the supporting base.

33. The thermoelectric device apparatus as recited in claim 30 wherein said thermal conduction means comprises:
a second pad disposed outside the first region, said second pad thermally coupled to one or more electrodes of the second group and electrically isolated from all but at most one electrode of the second group; and
a vertical structure thermally coupling the second pad to the supporting base.

34. The thermoelectric device apparatus as recited in claim 33 wherein said thermal means further comprises:
a third pad disposed outside the first region, said third pad thermally coupled to one or more electrodes of the second group and electrically isolated from all but at most one electrode of the second group; and
a vertical structure thermally coupling the third pad to the supporting base;
wherein each of the second and third pads is thermally coupled to a respective approximately half of the electrodes of the second group.

35. The thermoelectric device apparatus as recited in claim 31 comprising electrodes of at least one of the first and second groups of electrodes which are non-uniform in width within the first region.

36. The thermoelectric device apparatus as recited in claim 31 wherein:
the supporting layer group comprises a material chosen from the group consisting of polymers based upon paraxylylene and its substituted derivatives, fluoropolymers, and aerogels; and
the first pad overlaps the electrodes of the first group outside the first region and is vertically separated from the electrodes of the first group by a dielectric layer.

37. The thermoelectric device apparatus as recited in claim 36 wherein each respective lateral space between adjacent electrodes of a respective pair of adjacent electrodes is less than an electron-phonon thermalization length of a thermoelectric material comprising the respective thermoelectric element coupling together said respective pair of adjacent electrodes.

38. The thermoelectric device apparatus as recited in claim 37 wherein the thermoelectric device has a thermoelectric element figure of merit (ZT) greater than approximately 1.

39. A thermoelectric device apparatus comprising:
a plurality of laterally spaced-apart electrodes, each of said electrodes being thicker in a region between opposing longitudinal edges thereof than along said opposing longitudinal edges;
a plurality of thermoelectric elements, each coupling together at least respective longitudinal edges of laterally adjacent electrodes.

40. The thermoelectric device apparatus as recited in claim 39 wherein said thicker region of each electrode comprises a cross-section having generally a trapezoidal shape.

41. The thermoelectric device apparatus as recited in claim 39 further comprising a supporting structure upon which the thermoelectric elements and electrodes are disposed.

42. The thermoelectric device apparatus as recited in claim 41 wherein the supporting structure comprises a monolithic fabrication substrate.

43. The thermoelectric device apparatus as recited in claim 42 wherein the monolithic fabrication substrate comprises a silicon wafer.

44. The thermoelectric device apparatus as recited in claim 42 wherein the monolithic fabrication substrate comprises a sapphire substrate; a silicon-on-sapphire substrate, a glass substrate, a borosilicate substrate, a metal substrate, or a sintered alumina substrate.

45. The thermoelectric device apparatus as recited in claim 41 wherein the supporting structure comprises at least one thermally insulating layer.

46. The thermoelectric device apparatus as recited in claim 45 wherein the supporting structure further comprises a monolithic fabrication substrate upon which the at least one thermally insulating layer is disposed.

47. The thermoelectric device apparatus as recited in claim 45 wherein the at least one thermally insulating layer comprises a material chosen from the group consisting of dielectrics having a thermal conductivity of less than 0.1 W/m-K, polymers based upon paraxylylene and its substituted derivatives, fluoropolymers, and aerogels.

48. The thermoelectric device apparatus as recited in claim 45 wherein the at least one thermally insulating layer comprises two dissimilar material layers.

49. The thermoelectric device apparatus as recited in claim 41 wherein the supporting structure comprises a carrier substrate attached after monolithic fabrication of the thermoelectric elements and electrodes.

50. The thermoelectric device apparatus as recited in claim 39 wherein:
the plurality of laterally spaced-apart electrodes comprises first and second groups of electrodes disposed on a supporting structure in an alternating, laterally spaced apart manner within a first region, each electrode comprising opposing longitudinal edges having a first thickness and a central region between said opposing longitudinal edges having a second thickness greater than said first thickness; and
wherein the plurality of thermoelectric elements comprises alternating complementary thermoelectric elements, each element coupling together an electrode of the first group and an adjacent electrode of the second group within the first region.

51. The thermoelectric device apparatus as recited in claim 50 comprising electrodes of at least one of the first and second groups of electrodes which are non-uniform in width within the first region.

52. The thermoelectric device apparatus as recited in claim 50 wherein the supporting structure comprises:
a group of at least one supporting layer disposed on a supporting base, the supporting layer group having a substantially lower thermal conductivity than the supporting base.

53. The thermoelectric device apparatus as recited in claim 52 wherein:
the support base comprises a monolithic fabrication substrate; and
the supporting layer group comprises at least one deposited thermally insulating layer of a material chosen from the group consisting of dielectrics having a thermal conductivity of less than 0.1 W/m-K, polymers based upon paraxylylene and its substituted derivatives, fluoropolymers, and aerogels.

54. The thermoelectric device apparatus as recited in claim 52 further comprising:
thermal conduction means for providing thermal conduction between the electrodes of the second group and the supporting base that is substantially greater than any thermal conduction between the electrodes of the first group and the supporting base.

55. A complementary lateral thermoelectric device that is disposed upon a supporting layer comprising a material chosen from the group consisting of polymers based upon paraxylylene and its substituted derivatives, fluoropolymers, and aerogels.

56. The complementary lateral thermoelectric device as recited in claim 55 comprising a plurality of laterally spaced-apart electrodes disposed upon the supporting layer, each of said electrodes being thicker in a region between opposing longitudinal edges thereof than along said opposing longitudinal edges.

57. The complementary lateral thermoelectric device as recited in claim 56 further comprising a plurality of thermoelectric elements, each coupling together at least respective longitudinal edges of laterally adjacent electrodes.
